(19) United States
(12) Patent Application Publication
(10) Pub. No.: US 2023/0343684 A1
(43) Pub. Date: Oct. 26, 2023

(54) SEMICONDUCTOR DEVICE

(71) Applicant: ROHM CO., LTD., Kyoto-shi (JP)

(72) Inventors: Tomohira KIKUCHI, Kyoto-shi (JP); Hiroaki MATSUBARA, Kyoto-shi (JP); Yoshizo OSUMI, Kyoto-shi (JP); Moe YAMAGUCHI, Kyoto-shi (JP); Ryohei UMENO, Kyoto-shi (JP)

(21) Appl. No.: 18/343,290

(22) Filed: Jun. 28, 2023

Related U.S. Application Data
(63) Continuation of application No. PCT/JP2021/044725, filed on Dec. 6, 2021.

(30) Foreign Application Priority Data
Jan. 4, 2021 (JP) 2021-000237

(51) Int. Cl. H01L 23/495; H01L 23/31; H01L 23/00

(52) U.S. Cl. CPC H01L 23/49575; H01L 23/3107; H01L 23/49503; H01L 24/48; H01L 23/49562; H01L 2224/48245

(57) ABSTRACT

A semiconductor device includes a semiconductor control element, a first drive element, a second drive element, a first insulating element and a second insulating element. In plan view, the first drive element and the second drive element are located on the opposite sides with respect to the semiconductor control element. The first insulating element is located between the semiconductor control element and the first drive element, relays a signal transmitted from the semiconductor control element to the first drive element, and provides electrical insulation between the semiconductor control element and the first drive element. The second insulating element is located between the semiconductor control element and the second drive element, relays a signal transmitted from the semiconductor control element to the second drive element, and provides electrical insulation between the semiconductor control element and the second drive element.

### TECHNICAL FIELD

The present disclosure relates to semiconductor devices.

### BACKGROUND ART

Inverter devices have been used in electronic vehicles and consumer electronics. An inverter device includes a plurality of power semiconductors, such as insulated gate bipolar transistors (IGBTs) and metal-oxide-semiconductor field-effect transistors (MOSFETs), and a plurality of semiconductor devices incorporating insulating elements and serving as insulated gate drivers for generating drive signals for the power semiconductors. Each semiconductor device includes a semiconductor control element, an insulating element and a drive element. A control signal issued from an engine control unit (ECU) to the inverter device is inputted to the semiconductor control element of a semiconductor device. The semiconductor control element converts the control signal to a pulse width modulation (PWM) control signal, which is then transmitted to the drive element via the insulating element. The drive element generates a drive signal based on the PWM control signal and inputs the resulting signal to a power semiconductor to switch the power semiconductor on and off with desired timing. By switching six power semiconductors on and off at desired times, an inverter device can generate AC power for driving the motor from the DC power fed from a vehicle-mounted battery. An example of a semiconductor device that includes an insulating element is disclosed, for example, in JP-A-2016-207714.

A typical inverter device includes a plurality of half-bridge circuits each composed of two power semiconductors. The power semiconductors of each half-bridge circuit receive a drive signal from a semiconductor device. As the semiconductor device disclosed in JP-A-2016-207714 is for generating a drive signal for one power semiconductor, two such semiconductor devices are mounted on the wiring board of the inverter device per half-bridge circuit. In view of a demand for downsizing inverter devices, the wiring board is desired to be as small as possible.

### BRIEF DESCRIPTION OF THE DRAWINGS

FIG. 1 is a plan view of a semiconductor device according to a first embodiment of the present disclosure.

FIG. 2 is a plan view of the semiconductor device of FIG. 1 with a sealing resin shown as transparent.

FIG. 3 is a front view of the semiconductor device of FIG. 1.

FIG. 4 is a rear view of the semiconductor device of FIG. 1.

FIG. 5 is a left-side view of the semiconductor device of FIG. 1.

FIG. 6 is a right-side view of the semiconductor device of FIG. 1.

FIG. 7 is a sectional view taken along line VII-VII of FIG. 2.

FIG. 8 is a sectional view taken along line VIII-VIII of FIG. 2.

FIG. 9 is a sectional view taken along line IX-IX of FIG. 2.

FIG. 10 is a sectional view taken along line X-X of FIG. 2.

FIG. 11 is a sectional view taken along line XI-XI of FIG. 1.

FIG. 12 is a sectional view taken along line XII-XII of FIG. 1.

FIG. 13 is a plan view illustrating a process of manufacturing the semiconductor device of FIG. 1.

FIG. 14 is a plan view illustrating a process of manufacturing the semiconductor device of FIG. 1.

FIG. 15 is a plan view illustrating a process of manufacturing the semiconductor device of FIG. 1.

FIG. 16 is a plan view of a semiconductor device according to a second embodiment of the present disclosure, with a sealing resin shown as transparent.

FIG. 17 is a plan view of a semiconductor device according to a third embodiment of the present disclosure.

FIG. 18 is a plan view of a semiconductor device according to a fourth embodiment of the present disclosure.

FIG. 19 is a plan view of a semiconductor device according to a fifth embodiment of the present disclosure, with a sealing resin shown as transparent.

FIG. 20 is a plan view of a semiconductor device according to a sixth embodiment of the present disclosure, with a sealing resin shown as transparent.

### DETAILED DESCRIPTION OF EMBODIMENTS

Hereinafter, preferred embodiments of the present disclosure will be described with reference to the accompanying drawings.

Unless otherwise noted, the phrases such as “an object A is formed in an object B” and “an object A is formed on an object B” used in the present disclosure include “the object A is formed in direct contact with the object B” and “the object A is formed on the object B with another object interposed between the object A and the object B”. Similarly, unless otherwise noted, the phrases such as “an object A is arranged in an object B” and “an object A is arranged on an object B” include “the object A is arranged with direct contact with the object B” and “the object A is arranged on the object B with another object interposed between the object A and the object B”. Similarly, unless otherwise noted, the phrase such as “an object A is located on an object B” include “the object A is located on the object B with direct contact between the object A and the object B” and “the object A is located on the object B with another object interposed between the object A and the object B”. Additionally, unless otherwise noted, the phrase such as “an object A overlaps with an object B as viewed in a certain direction” includes “the object A overlaps with the entire object B as viewed in the direction” and “the object A overlaps with a portion of the object B as viewed in the direction”.

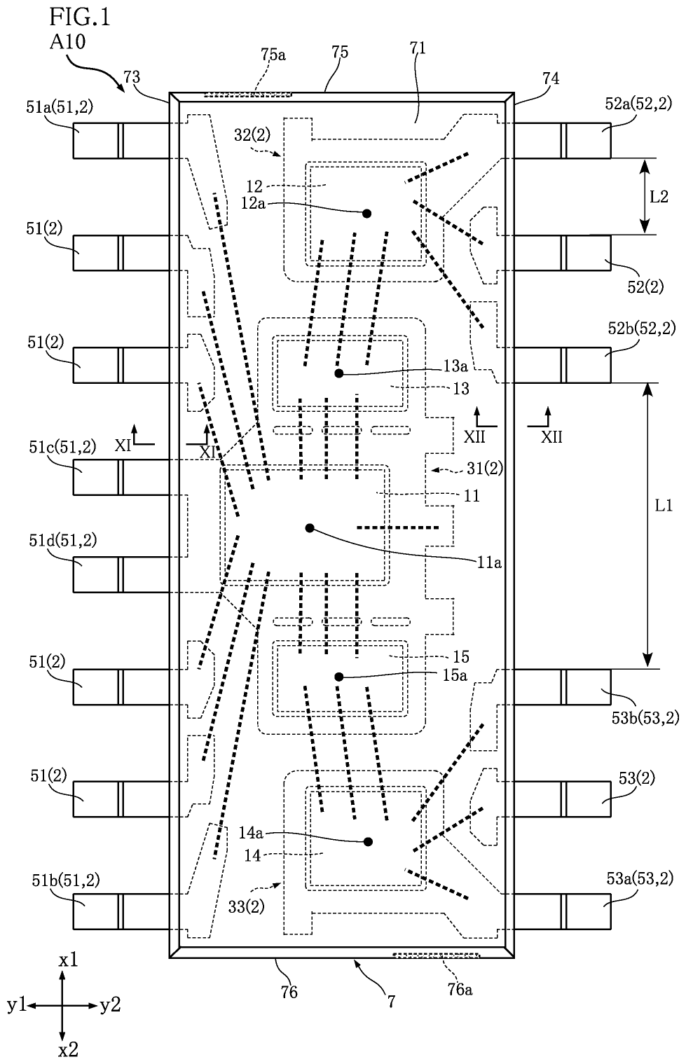

FIGS. 1 to 12 show an example of a semiconductor device according to a first embodiment of the present disclosure. A semiconductor device A10 according to the present embodiment includes a semiconductor control element 11, a first drive element 12, a first insulating element 13, a second drive element 14, a second insulating element 15, an electroconductive support member 2, a plurality of wires 61 to 67 and a sealing resin 7. The electroconductive support member 2 includes a first die pad 31, a second die pad 32, a third die pad 33, a plurality of input-side terminals 51, a plurality of first output-side terminals 52, a plurality of second output-side terminals 53 and a plurality of pad portions 54 to 56. The semiconductor device A10 may be, but not limited to, for surface mounting on a wiring board of an inverter device of, for example, an electric vehicle (e.g., a hybrid vehicle). The semiconductor device A10 is not limited to specific applications and/or functions. The semiconductor device A10 may be, but not limited to, a small outline package (SOP) device.

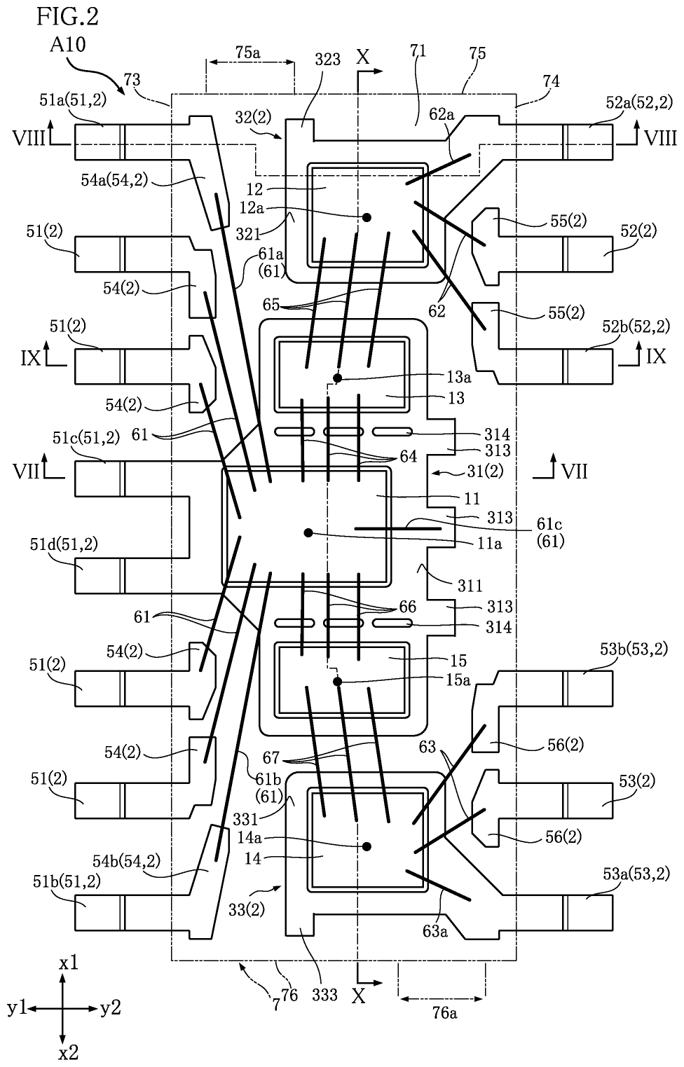

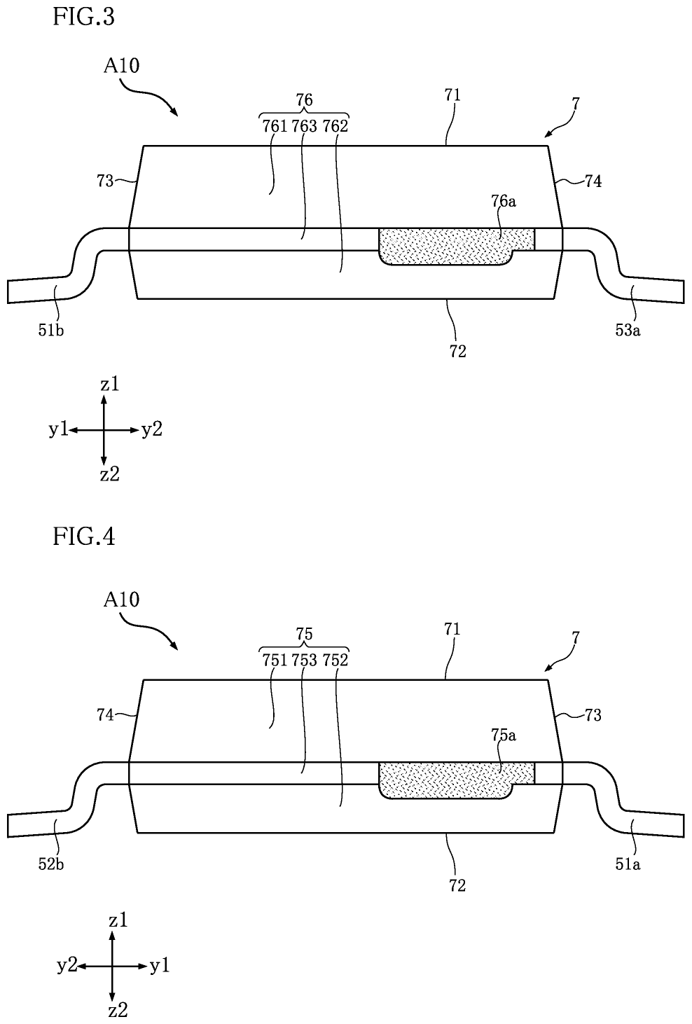

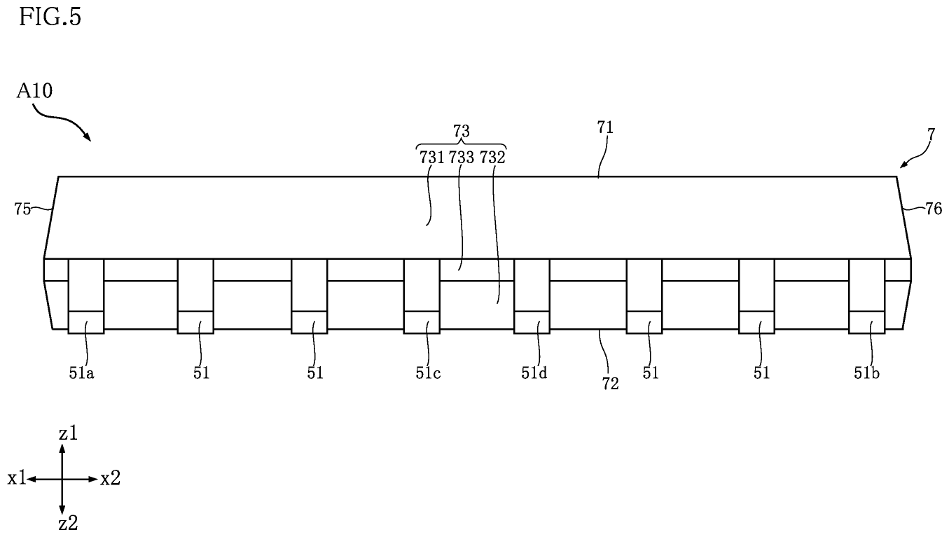

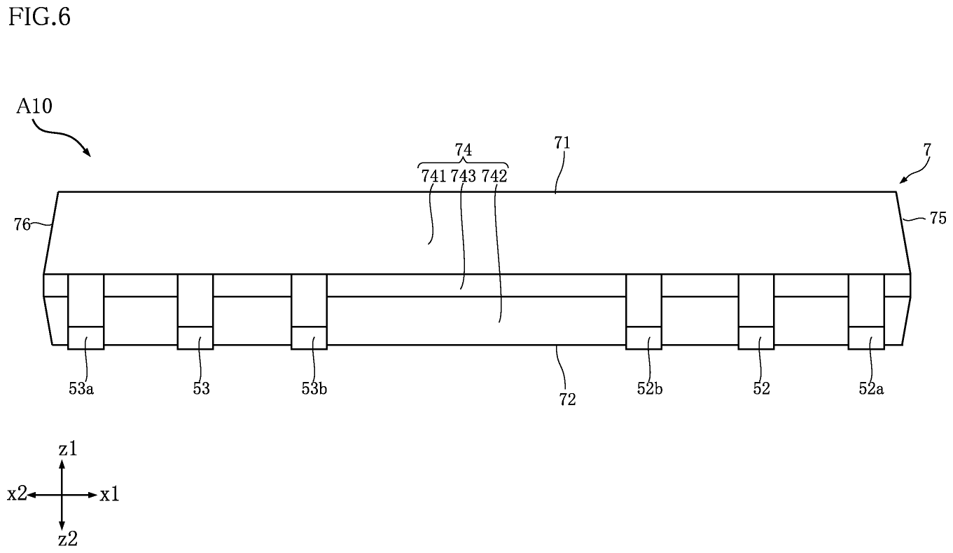

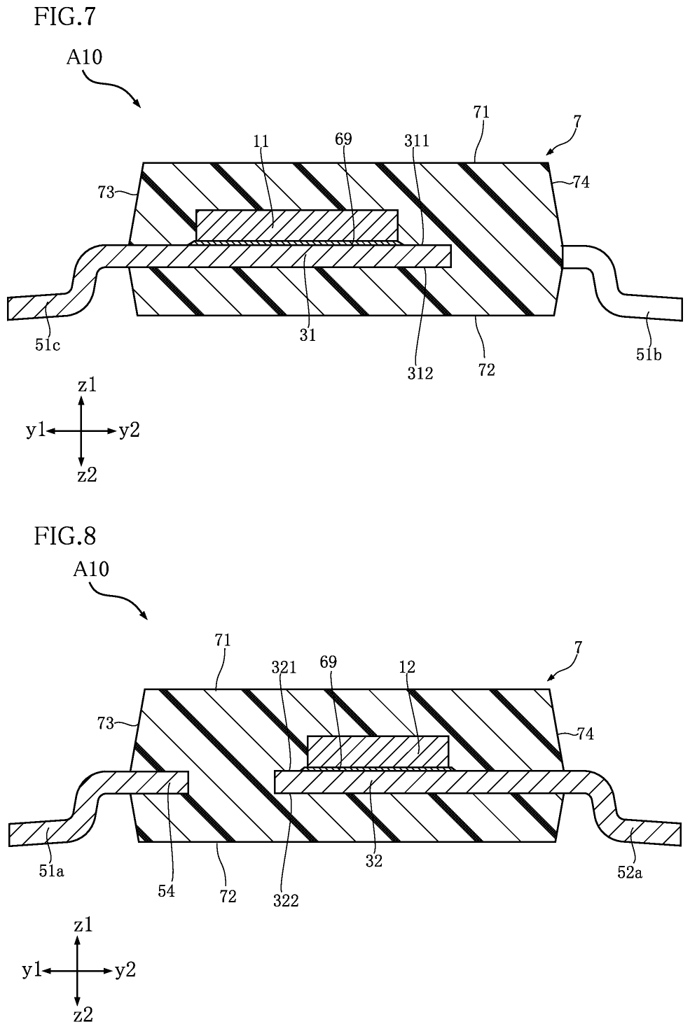

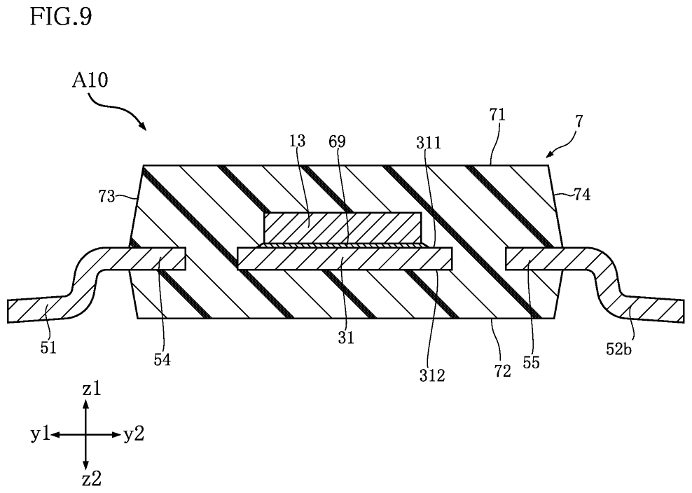

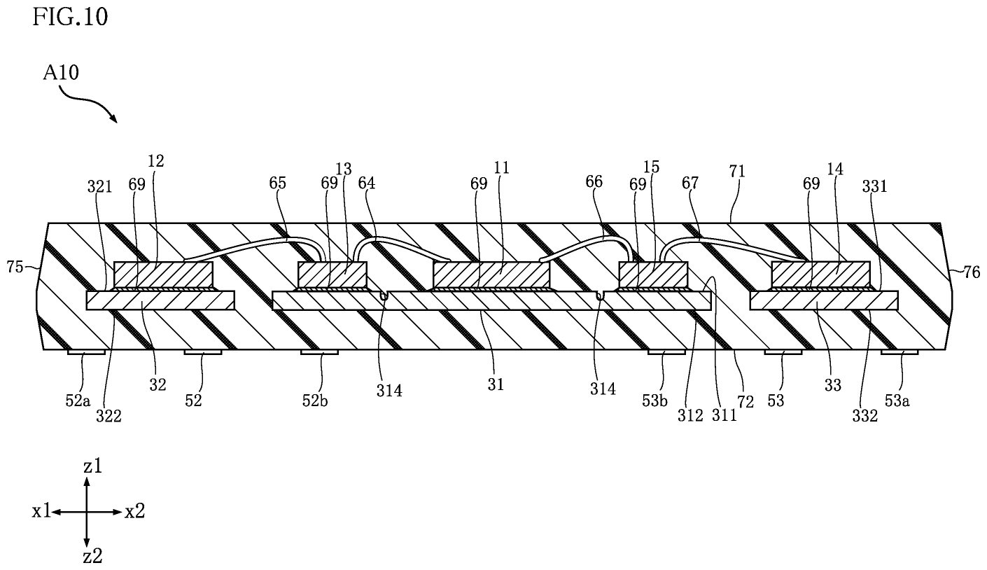

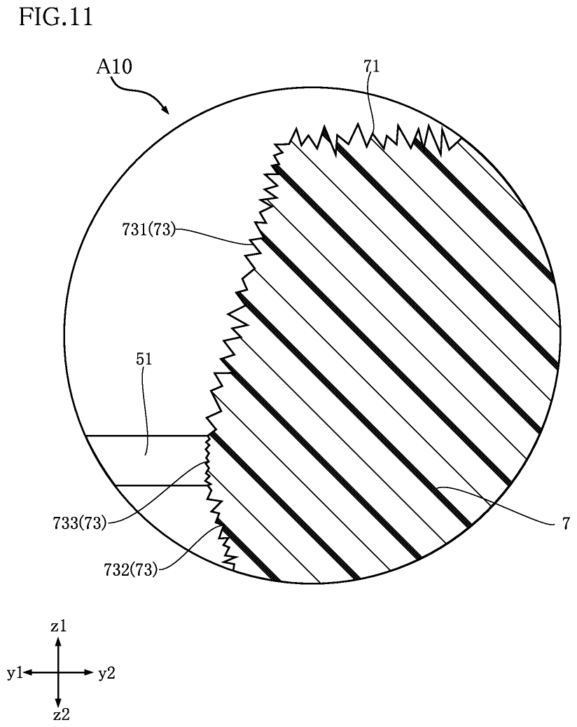

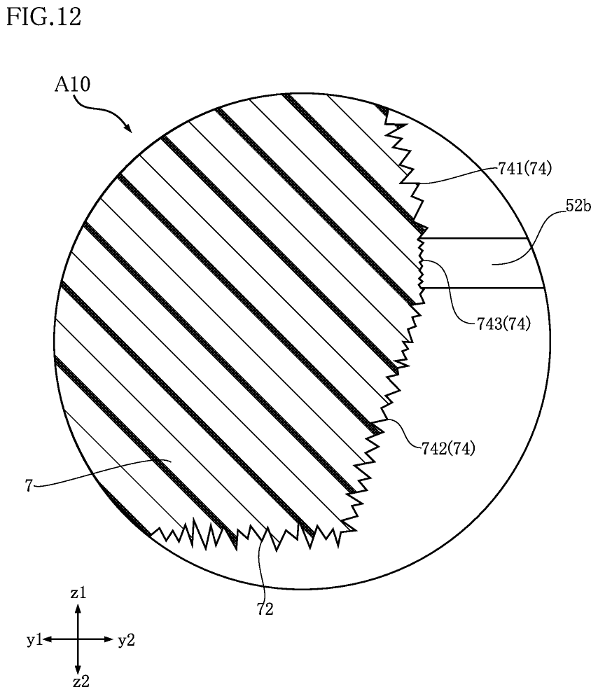

FIG. 1 is a plan view of the semiconductor device A10. FIG. 2 is a plan view of the semiconductor device A10. For convenience, FIG. 2 shows the sealing resin 7 as transparent and shows the outline of the sealing resin 7 in phantom (two-dot-dash lines). FIG. 3 is a front view of the semiconductor device A10. FIG. 4 is a rear view of the semiconductor device A10. FIG. 5 is a left-side view of the semiconductor device A10. FIG. 6 is a right-side view of the semiconductor device A10. FIG. 7 is a sectional view taken along line VII-VII of FIG. 2. FIG. 8 is a sectional view taken along line VIII-VIII of FIG. 2. FIG. 9 is a sectional view taken along line IX-IX of FIG. 2. FIG. 10 is a sectional view taken along line X-X of FIG. 2. FIG. 11 is a sectional view taken along line XI-XI of FIG. 1. FIG. 12 is a sectional view taken along line XII-XII of FIG. 1.

The semiconductor device A10 has the shape of an oblong rectangle as viewed in the thickness direction (in plan view). For convenience, the thickness direction of the semiconductor device A10 is designated as the z direction. A direction perpendicular to the z direction and parallel to one side of the semiconductor device A10 (the vertical direction as seen in the FIGS. 1 and 2) is designated as the x direction. The direction perpendicular to the z and x directions (the lateral direction as seen in the FIGS. 1 and 2) is designated as the y direction. The x direction is an example of the “first direction”, and the y direction as the “second direction”. The shapes and dimensions of the semiconductor device A10 are not specifically limited.

In one example, the semiconductor control element 11, the first drive element 12, the first insulating element 13, the second drive element 14 and the second insulating element 15 are integral elements to the functionality of the semiconductor device A10.

As shown in FIG. 2, the semiconductor control element 11, which is mounted on a portion of the electroconductive support member 2 (the first die pad 31 as described later), is located at the center of the semiconductor device A10 in the x direction and offset to the y1 side in the y direction. The semiconductor control element 11 has a rectangular shape elongated in the y direction as viewed in the z direction. The semiconductor control element 11 includes a circuit for converting a control signal inputted from, for example, an ECU into a PWM control signal and also includes a transmitting circuit for transmitting a PWM control signal to the first drive element 12 and the second drive element 14. In this embodiment, the semiconductor control element 11 receives a control signal for the high side and a control signal for the low side and transmits a PWM control signal for the high side to the first drive element 12 and a PWM control signal for the low side to the second drive element 14.

As shown in FIG. 2, the first drive element 12, which is mounted on a portion of the electroconductive support member 2 (the second die pad 32 as described later), is located at the end of the semiconductor device A10 on the x1 side in the x direction. In the y direction, the first drive element 12 is offset to the y2 side. The first drive element 12 has a rectangular shape elongated in the y direction as viewed in the z direction. The first drive element 12 includes a receiving circuit for receiving a PWM control signal transmitted from the semiconductor control element 11 and a circuit for issuing a drive signal (a gate driver) for driving a switching element (e.g., IGBT or MOSFET) based on the received PWM control signal. The first drive element 12 drives a high-side switching element.

As shown in FIG. 2, the second drive element 14, which is mounted on a portion of the electroconductive support member 2 (the third die pad 33 as described later), is located at the end of the semiconductor device A10 on the x2 side in the x direction. In the y direction, the second drive element 14 is offset to the y2 side. The second drive element 14 has a rectangular shape elongated in the y direction as viewed in the z direction. The second drive element 14 includes a receiving circuit for receiving a PWM control signal transmitted from the semiconductor control element 11 and a circuit for issuing a drive signal (a gate driver) for driving a switching element based on the received PWM control signal. The second drive element 14 drives a low-side switching element.

In this embodiment, the first drive element 12 drives a high-side switching element based on a high-side PWM control signal, and the second drive element 14 drives a low-side switching element based on a low-side PWM control signal. In an alternative example, the first drive element 12 may drive a low-side switching element based on a low-side PWM control signal, and the second drive element 14 may drive a high-side switching element based on a high-side PWM control signal.

As shown in FIG. 2, the first insulating element 13, which is mounted on a portion of the electroconductive support member 2 (the first die pad 31), is located at the center of the semiconductor device A10 in the y direction. In the x direction, the first insulating element 13 is located on the x2 side with respect to the first drive element 12 and on the x1 side with respect to the semiconductor control element 11. That is, the first insulating element 13 is located between the first drive element 12 and the semiconductor control element 11 in the x direction. The first insulating element 13 has a rectangular shape elongated in the y direction as viewed in the z direction. The first insulating element 13 is provided for transmitting a PWM control signal in an insulated condition. The first insulating element 13 receives a PWM control signal from the semiconductor control element 11 via the wires 64 and transmits the received PWM control signal to the first drive element 12 via the wires 65 in an insulated condition. That is, the first insulating element 13 provides a signal transmission between the first drive element 12 and the semiconductor control element 11, while also providing electrical insulation between the first drive element 12 and the semiconductor control element 11.

In this embodiment, the first insulating element 13 is of an inductive-coupling type. An inductive-coupling type insulating element implements insulated transmission of signals by inductively coupling two inductors (coils). The first insulating element 13 includes a substrate made of Si and inductors made of Cu on the substrate. The inductors include a transmitting-side inductor and a receiving-side inductor that are stacked with each other in the thickness direction (the z direction) of the first insulating element 13. A dielectric layer made of e.g. SiO₂ is interposed between the transmitting-side inductor and the receiving-side inductor. The dielectric layer electrically insulates the transmitting-side inductor and the receiving-side inductor. Although the first insulating element 13 of this embodiment is of an inductive type, the first insulating element 13 may be of a capacitive type. A capacitor is an example of a capacitive type insulating element.

As shown in FIG. 2, the second insulating element 15, which is mounted on a portion of the electroconductive support member 2 (the first die pad 31), is located at the center of the semiconductor device A10 in the y direction. In the x direction, the second insulating element 15 is located on the x1 side with respect to the second drive element 14 and on the x2 side with respect to the semiconductor control element 11. That is, the second insulating element 15 is located between the second drive element 14 and the semiconductor control element 11 in the x direction. The second insulating element 15 has a rectangular shape elongated in the y direction as viewed in the z direction. The second insulating element 15 is provided for transmitting a PWM control signal in an insulated condition. The second insulating element 15 receives a PWM control signal from the semiconductor control element 11 via the wires 66 and transmits the received PWM control signal to the second drive element 14 via the wires 67 in an insulated condition. That is, the second insulating element 15 provides a signal transmission between the second drive element 14 and the semiconductor control element 11, while also providing electrical insulation between the second drive element 14 and the semiconductor control element 11. In this embodiment, the second insulating element 15 is an inductive-coupling type insulating element as with the first insulating element 13. Alternatively, the second insulating element 15 may be of a capacitive type.

The semiconductor control element 11 transmits a high-side PWM control signal to the first drive element 12 via the first insulating element 13 and a low-side PWM control signal to the second drive element 14 via the second insulating element 15. Signals other than the PWM control signals may also be transmitted from the semiconductor control element 11 to the first drive element 12 via the first insulating element 13 and to the second drive element 14 via the second insulating element 15. Signals may also be transmitted from the first drive element 12 to the semiconductor control element 11 via the first insulating element 13. Signals may also be transmitted from the second drive element 14 to the semiconductor control element 11 via the second insulating element 15. Note that the signals transmitted from the first drive element 12 and the second drive element 14 to the semiconductor control element 11 may indicate any appropriate information and not specifically limited.

Generally, the motor driver circuit used in an inverter device of a hybrid vehicle, for example, is a half-bridge circuit composed of a low-side switching element and a high-side switching element connected by totem-pole configuration. An insulated gate driver turns on only one of the low-side switching element and the high-side switching element at an any given time. In the high-voltage region, the source of the low-side switching element and the reference voltage of the insulated gate driver for driving the low-side switching element are connected to ground, so that the setting of the gate-to-source voltage is relative to the ground. In contrast, the source of the high-side switching element and the reference voltage of the insulated gate driver for driving the high-side switching element are connected to the output node of the half-bridge circuit. The potential at the output node of the half-bridge circuit changes depending on which of the low-side switching element and the high-side switching element is on, so that the reference potential of the high-side insulated gate driver changes as well. When the high-side switching element is on, the reference potential is equal to the voltage applied to the drain of the high-side switching element (for example, 600 V or higher). In the semiconductor device A10, the first drive element 12 is used as an insulated gate driver for driving a high-side switching element. As the first drive element 12 and the semiconductor control element 11 are connected to different grounds for ensuring insulation, the first drive element 12 may be subjected to a transient voltage of 600 V or higher relative to the ground of the semiconductor control element 11. In light of such a large potential difference occurring between the first drive element 12 and the semiconductor control element 11, the semiconductor device A10 includes the first insulating element 13 that electrically isolates the input-side circuit including the semiconductor control element 11 and the first output-side circuit including the first drive element 12 from each other. That is, the first insulating element 13 provides electrical insulation between the input-side circuit held at lower potential and the first output-side circuit held at higher potential. Also, the semiconductor device A10 additionally includes the second insulating element 15 that electrically isolates the input-side circuit including the semiconductor control element 11 and the second output-side circuit including the second drive element 14 from each other. That is, the second insulating element 15 provides electrical insulation between the input-side circuit held at lower potential and the second output-side circuit held at higher potential.

A plurality of non-illustrated electrodes are provided on the upper surfaces (the surfaces on the z1 side) of the semiconductor control element 11, the first drive element 12, the first insulating element 13, the second drive element 14 and the second insulating element 15. In the x direction, the first drive element 12, the first insulating element 13, the semiconductor control element 11, the second insulating element 15 and the second drive element 14 are arranged in the stated order from the x1 side to the x2 side. As viewed in the y direction, the first drive element 12, the first insulating element 13, the semiconductor control element 11, the second insulating element 15 and the second drive element 14 do not overlap with each other, and an appropriate spacing is provided between them. The first insulating element 13 has a center 13a between the center 11a of the semiconductor control element 11 and the center 12a of the first drive element 12 in the y direction. The second insulating element 15 has a center 15a between the center 11a of the semiconductor control element 11 and the center 14a of the second drive element 14 in the y direction. That is, as viewed in the z direction, the semiconductor control element 11, the first drive element 12, the first insulating element 13, the second drive element 14 and the second insulating element 15 are arranged in the shape of a letter V that is open toward the y2 side in the y direction.

The electroconductive support member 2 forms conduction paths connecting the semiconductor control element 11, the first drive element 12 and the second drive element 14 of the semiconductor device A10 to the wiring board of an inverter device. The electroconductive support member 2 may be made of an alloy containing Cu, for example. The electroconductive support member 2 is formed from a leadframe 80, which will be described later. The electroconductive support member 2 supports the semiconductor control element 11, the first drive element 12, the first insulating element 13, the second drive element 14 and the second insulating element 15 mounted thereon. As shown in FIG. 2, the electroconductive support member 2 includes the first die pad 31, the second die pad 32, the third die pad 33, the input-side terminals 51, the first output-side terminals 52, the second output-side terminals 53 and the pad portions 54 to 56.

The first die pad 31 is located at the center of the semiconductor device A10 in the x direction and offset to the y1 side in the y direction. The second die pad 32 is located on the x1 side in the x direction with respect to the first die pad 31 and spaced apart from the first die pad 31. The third die pad 33 is located on the x2 side in the x direction with respect to the first die pad 31 and spaced apart from the first die pad 31.

As shown in FIGS. 2, 7, 9 and 10, the first die pad 31 has the semiconductor control element 11, the first insulating element 13 and the second insulating element 15 mounted thereon. The first die pad 31 is electrically connected to the semiconductor control element 11 and is one element of the input-side circuit described above. The first die pad 31 may have a rectangular (or substantially rectangular) shape elongated in the x direction as viewed in the z direction. The first die pad 31 has an obverse surface 311 and a reverse surface 312. The obverse surface 311 and the reverse surface 312 are spaced apart in the z direction as shown in FIGS. 7, 9 and 10. The obverse surface 311 is on the z1 side and the reverse surface 312 is on the z2 side. Each of the obverse surface 311 and the reverse surface 312 is flat (or substantially flat). As shown in FIGS. 2, 7, 9 and 10, the semiconductor control element 11, the first insulating element 13 and the second insulating element 15 are each bonded to the obverse surface 311 of the first die pad 31 by a bonding layer 69. The bonding layer 69 is made by solidifying a paste of metal, such as Ag. The bonding layer 69 is not limited to this example and may be made from a paste of solder or sintered metal or even from an insulating paste.

In this embodiment, the first die pad 31 includes a plurality of protrusions 313 and a plurality of grooves 314. As shown in FIGS. 2, the protrusions 313 protrude to the y2 side in the y direction from the side surface of the first die pad 31 on the y2 side in the y direction. In this embodiment, three protrusions 313 are provided at equal intervals in the x direction. The protrusions 313 are not exposed from the sealing resin 7. The protrusions 313 are the portions where the first die pad 31 is clamped and held firmly during the wire bonding in a manufacturing process. A wire 61c, which will be described later, is bonded to the middle one of the protrusions 313 in the x direction. The first die pad 31 may be provided with a plating layer covering the region of the obverse surface 311 corresponding to the middle protrusion 313. The plating layer may be made of metal containing Ag, for example. The plating layer serves to increase the strength of bonding to the wire 61c and protect the leadframe 80 (described later) from impact or shock at the time of bonding the wire 61c.

As shown in FIGS. 2 and 10, each groove 314 is recessed from the obverse surface 311 in the z direction and extends in the y direction. In this embodiment, the plurality of grooves 314 include three grooves aligned in the y direction at a location between the semiconductor control element 11 and the first insulating element 13 in the x direction and another three aligned at a location between the semiconductor control element 11 and the second insulating element 15. In this embodiment, the grooves 314 are formed by half-etching. The method of forming the grooves 314 is not limited to half-etching. For example, the grooves 314 may be formed by a stamping process of depressing appropriate portions of the obverse surface 311. The grooves 314 are provided to improve the adhesion of the sealing resin 7 to the first die pad 31. The shapes, locations and number of the grooves 314 to be provided are not specifically limited. In one example, the grooves 314 may penetrate the first die pad 31 in the z direction. In another example, the first die pad 31 may be without the grooves 314.

As shown in FIGS. 2, 8 and 10, the second die pad 32 has the first drive element 12 mounted thereon. The second die pad 32 is electrically connected to the first drive element 12 and is one element of the first output-side circuit described above. The second die pad 32 may have a rectangular (or substantially rectangular) shape as viewed in the z direction. The second die pad 32 has an obverse surface 321 and a reverse surface 322. The obverse surface 321 and the reverse surface 322 are spaced apart in the z direction as shown in FIGS. 8 and 10. The obverse surface 321 is on the z1 side and the reverse surface 322 is on the z2 side. Each of the obverse surface 321 and the reverse surface 322 is flat (or substantially flat). As shown in FIGS. 8 and 10, the first drive element 12 is bonded to the obverse surface 321 of the second die pad 32 by a bonding layer 69. As shown in FIG. 2, a wire 62a, which will be described later, is bonded to the obverse surface 321 at a location away from the first drive element 12 to the y2 side in the y direction. The second die pad 32 may be provided with a plating layer covering a region of the obverse surface 321 to which the wire 62a is bonded. The plating layer may be made of metal containing Ag, for example. The plating layer serves to increase the strength of bonding to the wire 62a and protect the leadframe 80 (described later) from impact or shock at the time of bonding the wire 62a.

In this embodiment, the second die pad 32 includes a protrusion 323. As shown in FIG. 2, the protrusion 323 protrudes to the x1 side in the x direction from the side surface of the second die pad 32 on the x1 side in the x direction. On the side surface, the protrusion 323 is offset to the y1 side in the y direction. The protrusion 323 is not exposed from the sealing resin 7. The protrusion 323 is a portion where the second die pad 32 is clamped and held firmly during the wire bonding in a manufacturing process.

As shown in FIGS. 2 and 10, the third die pad 33 has the second drive element 14 mounted thereon. The third die pad 33 is electrically connected to the second drive element 14 and is one element of the second output-side circuit described above. The third die pad 33 may have a rectangular (or substantially rectangular) shape as viewed in the z direction. The third die pad 33 has an obverse surface 331 and a reverse surface 332. The obverse surface 331 and the reverse surface 332 are spaced apart in the z direction as shown in FIG. 10. The obverse surface 331 is on the z1 side and the reverse surface 332 is on the z2 side. Each of the obverse surface 331 and the reverse surface 332 is flat (or substantially flat). As shown in FIG. 10, the second drive element 14 is bonded to the obverse surface 331 of the third die pad 33 by a bonding layer 69. As shown in FIG. 2, a wire 63a, which will be described later, is bonded to the obverse surface 331 at a location away from the second drive element 14 to the y2 side in the y direction. The third die pad 33 may be provided with a plating layer covering a region of the obverse surface 321 to which the wire 63a is bonded. The plating layer may be made of metal containing Ag, for example. The plating layer serves to increase the strength of bonding to the wire 63a and protect the leadframe 80 (described later) from impact or shock at the time of bonding the wire 63a.

In this embodiment, the third die pad 33 includes a protrusion 333. As shown in FIG. 2, the protrusion 333 protrudes to the x2 side in the x direction from the side surface of the third die pad 33 on the x2 side in the x direction. On the side surface, the protrusion 333 is offset to the y1 side in the y direction. The protrusion 333 is not exposed from the sealing resin 7. The protrusion 333 is a portion where the third die pad 33 is clamped and held firmly during the wire bonding in a manufacturing process.

The input-side terminals 51 form conduction paths connecting the semiconductor device A10 to the wiring board of an inverter device when bonded to the wiring board. The input-side terminals 51, which are electrically connected to the semiconductor control element 11 as necessary, are components of the input-side circuit described above. As shown in FIGS. 1, 2 and 5, the input-side terminals 51 are spaced apart from each other in the x direction at equal intervals. The input-side terminals 51 are located on the y1 side in the y direction with respect to the first die pad 31 and protrude to the y1 side in the y direction from the sealing resin 7 (the side surface 73 as described later). The input-side terminals 51 include a power supply terminal for receiving supply voltage, a ground terminal, and an input terminal for receiving a control signal. In this embodiment, the semiconductor device A10 includes, but not limited to, eight input-side terminals 51. Also, the signals inputted to and outputted from the input-side terminals 51 are not specifically limited.

Each input-side terminal 51 has a rectangular shape elongated in the y direction and includes a portion exposed from the sealing resin 7 and a portion covered with the sealing resin 7. As shown in FIGS. 7 to 9, the portion of each input-side terminal 51 exposed from the sealing resin 7 is bent into a gull-wing profile. Each input-side terminal 51 may be provided with a plating layer covering a portion exposed from the sealing resin 7. The plating layer may be made of an Sn-containing alloy, such as solder, and covers the portion exposed from the sealing resin 7. The plating layer improves the adhesion of solder to the exposed portion when the semiconductor device A10 is soldered to the wiring board of an inverter device and prevents erosion of the exposed portion which may be caused by the solder. The plurality of input-side terminals 51 include input-side terminals 51a, 51b, 51c and 51d. The input-side terminal 51a is the one of the input-side terminals 51 located farthest on the x1 side in the x direction. The input-side terminal 51b is the one of the input-side terminals 51 located farthest on the x2 side in the x direction. The input-side terminal 51c is the fourth one of the input-side terminals 51 counted from the farthest one on the x1 side in the x direction. The input-side terminal 51d is the fifth one of the input-side terminals 51 counted from the farthest one on the x1 side in the x direction. That is, the input-side terminals 51c and 51d are the pair of terminals located in the middle in the x direction among the plurality of input-side terminals 51. The input-side terminals 51c and 51d are connected to the first die pad 31 and support the first die pad 31.

Each input-side terminals 51 other than the input-side terminals 51c and 51d is connected to a pad portion 54 at the end on the y2 side in the y direction. Although the shapes of the pad portions 54 as viewed in the z direction are not specifically limited, each pad portion 54 in this embodiment has an elongated shape extending toward the first die pad 31. Each pad portion 54 has a flat (or substantially flat) upper surface (the surface on the z1 side), and a wire 61 is bonded thereto. The upper surface of each pad portion 54 may be plated. The plating layer may be made of metal containing Ag, for example, and covers the upper surface of the pad portion 54. The plating layer serves to increase the strength of bonding to the wire 61 and to protect the leadframe 80 from impact or shock expected at the time of bonding the wire 61. The pad portions 54 are entirely covered with the sealing resin 7. The plurality of pad portions 54 include a pad portion 54a and a pad portion 54b. The pad portion 54a is connected to the input-side terminal 51a. The pad portion 54b is connected to the input-side terminal 51b.

Similarly to the input-side terminals 51, the first output-side terminals 52 form conduction paths connecting the semiconductor device A10 to the wiring board of an inverter device when bonded to the wiring board. The first output-side terminals 52, which are electrically connected to the first drive element 12 as necessary, are components of the first output-side circuit described above. As shown in FIGS. 1, 2 and 6, the first output-side terminals 52 are spaced apart from each other in the x direction at equal intervals. The first output-side terminals 52 are located on the y2 side in the y direction with respect to the second die pad 32 and protrude to the y2 side in the y direction from the sealing resin 7 (the side surface 74 as described later). The first output-side terminals 52 include a power supply terminal for receiving supply voltage, a ground terminal, and an output terminal for outputting a drive signal. In this embodiment, the semiconductor device A10 includes, but not limited to, three first output-side terminals 52. Also, the signals inputted to and outputted from the first output-side terminals 52 are not specifically limited.

Each first output-side terminal 52 has a rectangular shape elongated in the y direction and includes a portion exposed from the sealing resin 7 and a portion covered with the sealing resin 7. As shown in FIGS. 7 to 9, the portion of each first output-side terminal 52 exposed from the sealing resin 7 is bent into a gull-wing profile. As with the input-side terminals 51, each first output-side terminal 52 may be provided with a plating layer (of an Sn-containing alloy, such as solder) covering the portion exposed from the sealing resin 7. The plurality of first output-side terminals 52 include a first output-side terminal 52a and a first output-side terminal 52b. The first output-side terminal 52a is the one of the first output-side terminals 52 located farthest on the x1 side in the x direction. The first output-side terminal 52a is connected to the second die pad 32 and supports the second die pad 32. The first output-side terminal 52b is the one of the first output-side terminals 52 located farthest on the x2 side in the x direction.

Each first output-side terminal 52 other than the first output-side terminal 52a is connected to a pad portion 55 at the end on the y1 side in the y direction. Although the shapes of the pad portions 55 as viewed in the z direction are not specifically limited, each pad portion 55 in this embodiment has an elongated shape extending in the x direction. Each pad portion 55 has a flat (or substantially flat) upper surface (the surface on the z1 side), and a wire 62 is bonded thereto. As with the upper surfaces of the pad portions 54, the upper surfaces of the pad portions 55 may be plated (with metal containing Ag, for example). The pad portions 55 are entirely covered with the sealing resin 7.

Similarly to the input-side terminals 51, the second output-side terminals 53 form conduction paths connecting the semiconductor device A10 to the wiring board of an inverter device when bonded to the wiring board. The second output-side terminals 53, which are electrically connected to the second drive element 14 as necessary, are components of the second output-side circuit described above. As shown in FIGS. 1, 2 and 6, the second output-side terminals 53 are located on the x2 side in the x direction with respect to the first output-side terminals 52 and are spaced apart from each other in the x direction at equal intervals. The second output-side terminals 53 are located on the y2 side in the y direction with respect to the third die pad 33 and protrude to the y2 side in the y direction from the sealing resin 7 (the side surface 74 as described later). The second output-side terminals 53 include a power supply terminal for receiving supply voltage, a ground terminal, au output terminal for outputting a drive signal. In this embodiment, the semiconductor device A10 includes, but not limited to, three second output-side terminals 53. Also, the signals inputted to and outputted from the second output-side terminals 53 are not specifically limited.

Each second output-side terminal 53 has a rectangular shape elongated in the y direction and includes a portion exposed from the sealing resin 7 and a portion covered with the sealing resin 7. As shown in FIG. 3, the portion of each second output-side terminal 53 exposed from the sealing resin 7 is bent into a gull-wing profile. As with the input-side terminals 51, each second output-side terminal 53 may be provided with a plating layer (of an Sn-containing alloy, such as solder) covering the portion exposed from the sealing resin 7. The plurality of second output-side terminals 53 include a second output-side terminal 53a and a second output-side terminal 53b. The second output-side terminal 53a is the one of the second output-side terminals 53 located farthest on the x2 side in the x direction. The second output-side terminal 53a is connected to the third die pad 33 and supports the third die pad 33. The second output-side terminal 53b is the one of the second output-side terminals 53 located farthest on the x1 side in the x direction.

Each second output-side terminal 53 other than the second output-side terminal 53a is connected to a pad portion 56 at the end on the y1 side in the y direction. Although the shapes of the pad portions 56 as viewed in the z direction are not specifically limited, each pad portion 56 in this embodiment has an elongated shape extending in the x direction. Each pad portion 56 has a flat (or substantially flat) upper surface (the surface on the z1 side), and a wire 63 is bonded to the upper surface. As with the upper surfaces of the pad portions 56, the upper surfaces of the pad portions 54 may be plated (with metal containing Ag, for example). The pad portions 56 are entirely covered with the sealing resin 7.

In the semiconductor device A10, the first drive element 12 may receive a transient voltage of 600 V or higher relative to the ground of the semiconductor control element 11. As a result, a significant potential difference may be caused between the first output-side terminals 52 electrically connected to the first drive element 12 and the input-side terminals 51 electrically connected to the semiconductor control element 11. In addition, as the potential difference between the second drive element 14 and the semiconductor control element 11 is relatively small, a significant potential difference may also be caused between the first output-side terminals 52 electrically connected to the first drive element 12 and the second output-side terminals 53 electrically connected to the second drive element 14.

In this embodiment, as shown in FIG. 1, a large separation distance is provided in the x direction between the portions of the first output-side terminals 52 exposed from the sealing resin 7 and the portions of the second output-side terminals 53 exposed from the sealing resin 7. Specifically, let a first inter-terminal distance L1 denote the separation distance between the exposed portion of the first output-side terminal 52b and the exposed portion of the second output-side terminal 53b, and a second inter-terminal distance L2 denote the separation distance between the exposed portions of a pair of two adjacent first output-side terminals 52. Then, the first inter-terminal distance L1 is about 3.5 times greater than the second inter-terminal distance L2. The first inter-terminal distance L1 is preferably, but not limited to, at least three times greater than the second inter-terminal distance L2. In the illustrated example, the first output-side terminals 52 are arranged at equal intervals in the x direction, so that the separation distance between each pair of two adjacent first output-side terminals 52 is the same. In an alternative example, the intervals between the first output-side terminals 52 may be not be uniform, in which case, the greatest one of the separation distances may be designated as the second inter-terminal distance L2.

As shown in FIG. 2, the wires 61 to 67 together with the electroconductive support member 2 form conduction paths for the semiconductor control element 11, the first drive element 12 and the second drive element 14 to perform their functions. The wires 61 to 64 may each be made of metal, such as Au, Cu or Al.

The wires 61 form conduction paths connecting the semiconductor control element 11 and the input-side terminals 51. With the wires 61, the semiconductor control element 11 is electrically connected to at least one of the input-side terminals 51. The wires 61 are components of the input-side circuit described above. Each wire 61 is bonded to an electrode of the semiconductor control element 11. The plurality of wires 61 include wires 61a, 61b and 61c. The wire 61a extends from the semiconductor control element 11 to the x1 side in the x direction and bonded to the pad portion 54a connected to the input-side terminal 51a. As such, the wire 61a is relatively long and passes through a region near the first insulating element 13 as viewed in the z direction. Yet, the wire 61a does not overlap with the first insulating element 13 as viewed in the z direction. The wire 61a forms a relatively small angle of 20° or less with the x direction. The wire 61a is an example of a “first wire”. The wire 61b extends from the semiconductor control element 11 to the x2 side in the x direction and bonded to the pad portion 54b connected to the input-side terminal 51b. As such, the wire 61b is relatively long and passes through a region near the second insulating element 15 as viewed in the z direction. Yet, the wire 61b does not overlap with the second insulating element 15 as viewed in the z direction. The wire 61b forms a relatively small angle of 20° or less with the x direction. The wire 61b is an example of a “second wire”. The wire 61c extends from the semiconductor control element 11 to the y2 side in the y direction and bonded to the protrusion 313 of the first die pad 31. In this way, the semiconductor control element 11 is electrically connected via the wire 61c and the first die pad 31 to the input-side terminals 51c and 51d. The numbers of the wires 61a, 61b and 61c to be provided are not specifically limited. Each wire 61 other than the wires 61a, 61b and 61c extends from the semiconductor control element 11 to the y1 side in the y direction and bonded to a pad portion 54. The number of the wires 61 bonded to each pad portion 54 is not specifically limited.

The wires 62 form conduction paths connecting the first drive element 12 and the first output-side terminals 52. With the wires 62, the first drive element 12 is electrically connected to at least one of the first output-side terminals 52. The wires 62 are components of the first output-side circuit described above. Each wire 62 is bonded to an electrode of the first drive element 12. The plurality of wires 62 include a wire 62a. The wire 62a extends from the first drive element 12 to the y2 side in the y direction and bonded to the second die pad 32. In this way, the first drive element 12 is electrically connected via the wire 62a and the second die pad 32 to the first output-side terminal 52a. The number of the wires 62a to be provided is not specifically limited. Each wire 62 other than the wire 62a extends from the first drive element 12 to the y2 side in the y direction and bonded to a pad portion 55. The number of the wires 62 to be bonded to each pad portion 55 is not specifically limited.

The wires 63 form conduction paths connecting the second drive element 14 and the second output-side terminals 53. With the wires 63, the second drive element 14 is electrically connected to at least one of the second output-side terminals 53. The wires 63 are components of the second output-side circuit described above. Each wire 63 is bonded to an electrode of the second drive element 14. The plurality of wires 63 include a wire 63a. The wire 63a extends from the second drive element 14 to the y2 side in the y direction and bonded to the third die pad 33. In this way, the second drive element 14 is electrically connected via the wire 63a and the third die pad 33 to the second output-side terminal 53a. The number of the wires 63a to be provided is not specifically limited. Each wire 63 other than the wire 63a extends from the second drive element 14 to the y2 side in the y direction and bonded to a pad portion 56. The number of the wires 63 to be bonded to each pad portion 56 is not specifically limited.

As shown in FIGS. 2 and 10, the wires 64 form conduction paths connecting the semiconductor control element 11 and the first insulating element 13. With the wires 64, the semiconductor control element 11 and the first insulating element 13 are electrically connected to each other. The wires 64 are components of the input-side circuit described above. Each wire 64 extends in the x direction (or substantially in the x direction) to be bonded to an electrode of the semiconductor control element 11 and to an electrode of the first insulating element 13. The number of the wires 64 to be provided is not specifically limited.

As shown in FIGS. 2 and 10, the wires 65 form conduction paths connecting the first drive element 12 and the first insulating element 13. With the wires 65, the first drive element 12 and the first insulating element 13 are electrically connected to each other. The wires 65 are components of the first output-side circuit described above. Each wire 65 extends in the x direction (or substantially in the x direction) to be bonded to an electrode of the first drive element 12 and to an electrode of the first insulating element 13. The number of the wires 65 to be provided is not specifically limited.

As shown in FIGS. 2 and 10, the wires 66 form conduction paths connecting the semiconductor control element 11 and the second insulating element 15. With the wires 66, the semiconductor control element 11 and the second insulating element 15 are electrically connected to each other. The wires 66 are components of the input-side circuit described above. Each wire 66 extends in the x direction (or substantially in the x direction) to be bonded to an electrode of the semiconductor control element 11 and to an electrode of the second insulating element 15. The number of the wires 66 to be provided is not specifically limited.

As shown in FIGS. 2 and 10, the wires 67 form conduction paths connecting the second drive element 14 and the second insulating element 15. With the wires 67, the second drive element 14 and the second insulating element 15 are electrically connected to each other. The wires 67 are components of the second output-side circuit described above. Each wire 67 extends in the x direction (or substantially in the x direction) to be bonded to an electrode of the second drive element 14 and to an electrode of the second insulating element 15. The number of the wires 67 to be provided is not specifically limited.

As shown in FIG. 1, the sealing resin 7 covers the semiconductor control element 11, the first drive element 12, the first insulating element 13, the second drive element 14, the second insulating element 15, the first die pad 31, the second die pad 32, the third die pad 33, the pad portions 54 to 56, the wires 61 to 67, a portion of each input-side terminal 51, a portion of each first output-side terminal 52, and a portion of each second output-side terminal 53. The sealing resin 7 is electrically insulating. The sealing resin 7 is made of a material containing black epoxy resin, for example. The sealing resin 7 has a rectangular shape elongated in the y direction as viewed in the z direction. In this embodiment, the sealing resin 7 may have an x-direction dimension of about 9.0 to 11 mm, a y-direction dimension of about 3.5 to 4.5 mm and a z-direction dimension of about 1.3 to 1.5 mm, but the respective dimensions are not limited to these.

As shown in FIGS. 3 to 6, the sealing resin 7 includes a top surface 71, a bottom surface 72 and side surfaces 73 to 76.

The top surface 71 and the bottom surface 72 are spaced apart from each other in the z direction. The top surface 71 and the bottom surface 72 face away from each other in the z direction. The top surface 71 is on the z1 side in the z direction, facing the same side as the obverse surface 311 (the z1 side) of the first die pad 31. In other words, the top surface 71 is located on the side opposite the first die pad 31 with respect to the semiconductor control element 11. The bottom surface 72 is located on the z2 side in the z direction and faces the same z2 side as the reverse surface 312 of the first die pad 31. Each of the top surface 71 and the bottom surface 72 is flat (or substantially flat).

Each of the side surfaces 73 to 76 is connected to the top surface 71 and the bottom surface 72 and located between the top surface 71 and the bottom surface 72 in the z direction. The side surfaces 73 and 74 are spaced apart from each other in the y direction. The side surfaces 73 and 74 face away from each other in the y direction. The side surface 73 is located on the y1 side in the y direction, and the side surface 74 is located on the y2 side in the y direction. The side surfaces 75 and 76 are spaced apart from each other in the x direction and connected to the side surfaces 73 and 74. The side surfaces 75 and 76 face away from each other in the x direction. The side surface 75 is located on the x1 side in the x direction, and the side surface 76 is located on the x2 side in the x direction. As shown in FIG. 1, portions of the input-side terminals 51 protrude from the side surface 73. In addition, portions of the first output-side terminals 52 and of the second output-side terminals 53 protrude from the side surface 74. Yet, in the region of the side surface 74 between the first output-side terminal 52b and the second output-side terminal 53b, the electroconductive support member 2 is not exposed. In addition, the electroconductive support member 2 is not exposed on the side surfaces 75 and 76 either. The side surface 74 is an example of a “first side surface”, the side surface 75 is an example of a “second side surface” and the side surface 76 is an example of a “third side surface”.

As shown in FIG. 5, the side surface 73 includes an upper region 731, a lower region 732 and a middle region 733. The upper region 731 is connected to the top surface 71 at one end in the z direction and to the middle region 733 at the other end in the z direction. The upper region 731 is inclined relative to the top surface 71. The lower region 732 is connected to the bottom surface 72 at one end in the z direction and to the middle region 733 at the other end in the z direction. The lower region 732 is inclined relative to the bottom surface 72. The middle region 733 is connected to the upper region 731 at one end in the z direction and to the lower region 732 at the other end in the z direction. The middle region 733 is parallel to both the z direction and the x direction. As viewed in the z direction, the middle region 733 is located outside the top surface 71 and the bottom surface 72. The middle region 733 is where the portions of the input-side terminals 51 are exposed.

As shown in FIG. 6, the side surface 74 includes an upper region 741, a lower region 742 and a middle region 743. The upper region 741 is connected to the top surface 71 at one end in the z direction and to the middle region 743 at the other end in the z direction. The upper region 741 is inclined relative to the top surface 71. The lower region 742 is connected to the bottom surface 72 at one end in the z direction and to the middle region 743 at the other end in the z direction. The lower region 742 is inclined relative to the bottom surface 72. The middle region 743 is connected to the upper region 741 at one end in the z direction and to the lower region 742 at the other end in the z direction. The middle region 743 is parallel to both the z direction and the x direction. As viewed in the z direction, the middle region 743 is located outside the top surface 71 and the bottom surface 72. The middle region 743 is where the portions of the first output-side terminals 52 and of the second output-side terminals 53 are exposed.

As shown in FIG. 4, the side surface 75 includes an upper region 751, a lower region 752 and a middle region 753. The upper region 751 is connected to the top surface 71 at one end in the z direction and to the middle region 753 at the other end in the z direction. The upper region 751 is inclined relative to the top surface 71. The lower region 752 is connected to the bottom surface 72 at one end in the z direction and to the middle region 753 at the other end in the z direction. The lower region 752 is inclined relative to the bottom surface 72. The middle region 753 is connected to the upper region 751 at one end in the z direction and to the lower region 752 at the other end in the z direction. The middle region 753 is parallel to both the z direction and the y direction. As viewed in the z direction, the middle region 753 is located outside the top surface 71 and the bottom surface 72.

As shown in FIG. 4, the side surface 75 has a first gate mark 75a. The first gate mark 75a has a rougher surface than the other region of the side surface 75. The first gate mark 75a is formed during the manufacture of the semiconductor device A10 in the later-described process of forming the sealing resin 7. The first gate mark 75a is formed by removing resin burrs left at the site of the inlet gate of a melted resin. As shown in FIG. 1, the first gate mark 75a is offset in the y direction to the y1 side. Specifically, the first gate mark 75a is located on the y1 side in the y direction with respect to the center 12a of the first drive element 12 (closer to the center 11a of the semiconductor control element 11).

As shown in FIG. 3, the side surface 76 includes an upper region 761, a lower region 762 and a middle region 763. The upper region 761 is connected to the top surface 71 at one end in the z direction and to the middle region 763 at the other end in the z direction. The upper region 761 is inclined relative to the top surface 71. The lower region 762 is connected to the bottom surface 72 at one end in the z direction and to the middle region 763 at the other end in the z direction. The lower region 762 is inclined relative to the bottom surface 72. The middle region 763 is connected to the upper region 761 at one end in the z direction and to the lower region 762 at the other end in the z direction. The middle region 763 is parallel to both the z direction and the y direction. As viewed in the z direction, the middle region 763 is located outside the top surface 71 and the bottom surface 72.

As shown in FIG. 3, the side surface 76 has a second gate mark 76a. The second gate mark 76a has a rougher surface than the other region of the side surface 76. The second gate mark 76a is formed during the manufacture of the semiconductor device A10 in the later-described process of forming the sealing resin 7. The second gate mark 76a is formed by removing resin burrs left at the site of the outlet gate of a melted resin. As shown in FIG. 1, the second gate mark 76a is offset in the y direction to the y2 side. Specifically, the second gate mark 76a is located on the y2 side in the y direction (opposite the center 11a of the semiconductor control element 11) with respect to the center 14a of the second drive element 14.

In this embodiment, as shown in FIGS. 11 and 12, the sealing resin 7 has a greater surface roughness on the top surface 71, the bottom surface 72, and each of the upper region 731 and the lower region 732 of the side surface 73 than on the middle region 733 of the side surface 73. Also, the sealing resin 7 has a greater surface roughness on the top surface 71, the bottom surface 72, and each of the upper region 741 and the lower region 742 of the side surface 74 than on the middle region 743 of the side surface 74. The surface roughness of each of the top surface 71 and the bottom surface 72 is preferably between 5 and 20 μm Rz. The upper region 741 is an example of a “first region”, the lower region 742 is an example of a “second region”, and the middle region 743 is an example of a “third region”.

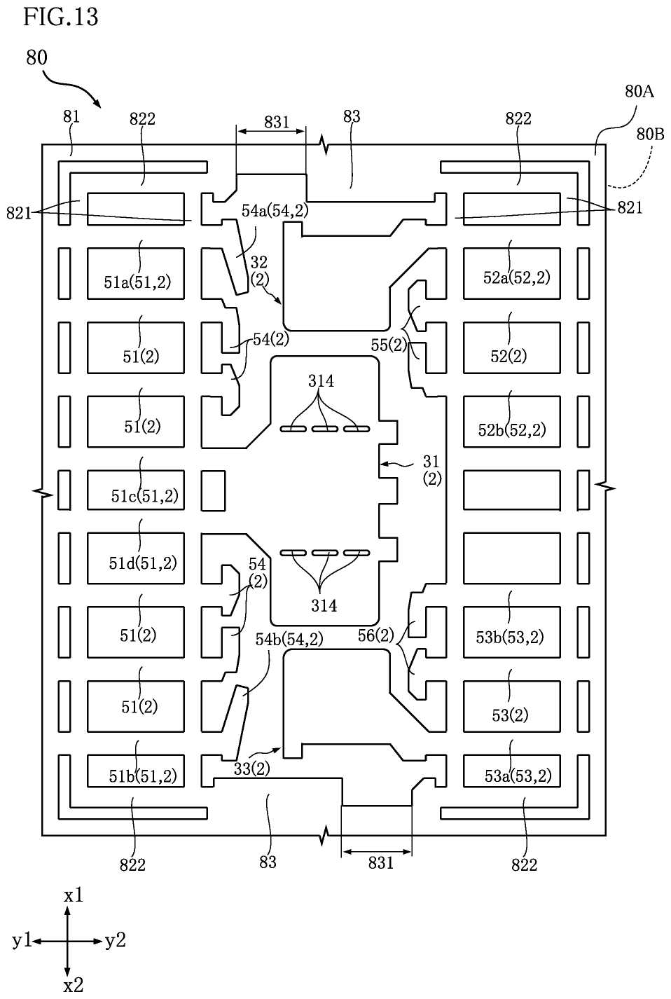

Next, a method of manufacturing the semiconductor device A10 is described below with reference to FIGS. 13 to 15. FIGS. 13 to 15 are plan views illustrating processes of manufacturing the semiconductor device A10. The x, y and z directions shown in the figures correspond to those shown in FIGS. 1 to 12.

First, a leadframe 80 is prepared as shown in FIG. 13. The leadframe 80 is a plate-like material. In this embodiment, the base material of the leadframe 80 is Cu. The leadframe 80 may be made from a metal plate by etching and, if necessary, other processing. The leadframe 80 is a flat frame without depressions. The leadframe 80 has an obverse surface 80A and a reverse surface 80B spaced apart from each other in the z direction. The grooves 314 are formed by half-etching the obverse surface 80A. The leadframe 80 may be formed by punching of a metal plate. In this case, the grooves 314 are formed by stamping on the obverse surface 80A.

The leadframe 80 includes the electroconductive support member 2 (the first die pad 31, the second die pad 32, the third die pad 33, the input-side terminals 51, the first output-side terminals 52, the second output-side terminals 53 and the pad portions 54 to 56) and additionally includes a frame 81, a plurality of first tie bars 821, a plurality of second tie bars 822 and a pair of dam bars 83. The frame 81, the first tie bars 821, the second tie bars 822 and the dam bars 83 do not form parts of the semiconductor device A10.

As viewed in the z direction, the frame 81 is a closed rectangular structure. The frame 81 surrounds the electroconductive support member 2, the first tie bars 821, the second tie bars 822 and the dam bars 83. The input-side terminals 51 are tied to the frame 81 at their ends on the y1 side in the y direction. The first output-side terminals 52 and the second output-side terminals 53 are tied to the frame 81 at their ends on the y2 side in the y direction.

The first tie bars 821 extend in the x direction. Each first tie bar 821 is tied to a pair of second tie bars 822 at their opposite ends in the x direction. The plurality of first tie bars 821 include a pair of first tie bars 821 located on the y1 side in the y direction and a pair of first tie bars 821 located on the y2 side in the y direction. The input-side terminals 51 are tied to the pair of first tie bars 821 located on the y1 side in the y direction. The first output-side terminals 52 and the second output-side terminals 53 are tied to the pair of first tie bars 821 located on the y2 side in the y direction.

The second tie bars 822 extend in the y direction. Each second tie bar 822 is tied to a dam bar 83 at an end in the y direction. The plurality of second tie bars 822 include a pair of second tie bars 822 located on the y1 side in the y direction and a pair of second tie bars 822 located on the y2 side in the y direction. On each of the y1 side and the y2 side, the pair of second tie bars 822 and the pair of first tie bars 821 form closed rectangular structure as viewed in the z direction.

The pair of dam bars 83 are provided at the ends of the leadframe 80 in the x direction. Each dam bar 83 extends in the y direction and protrudes toward the electroconductive support member 2. Each dam bar 83 has a cutout portion 831. The cutout portions 831 serve as a gate through which melted resin enters and exits out at the time of molding the sealing resin 7.

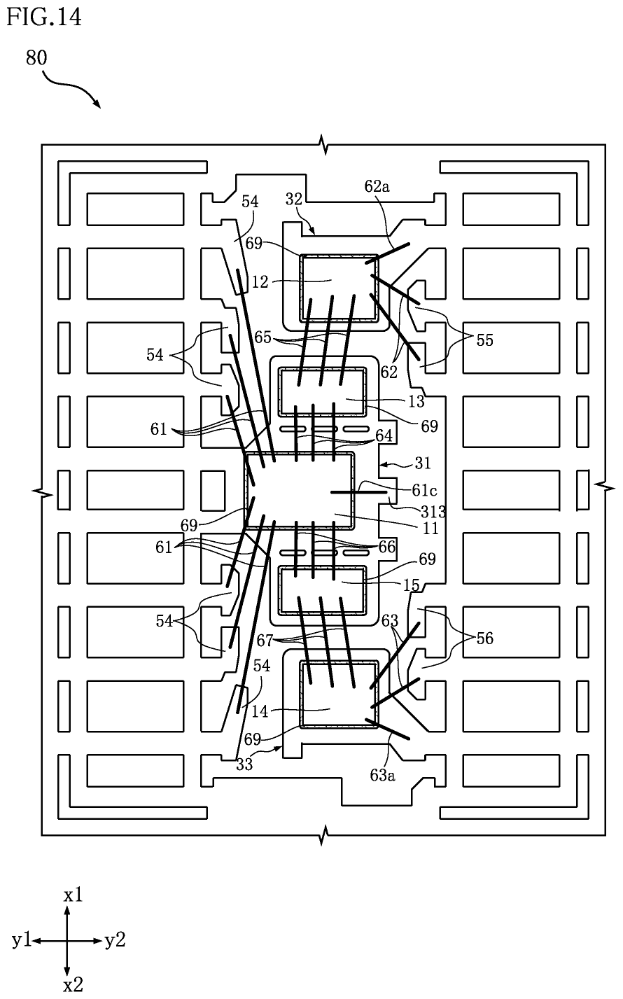

Next, as shown in FIG. 14, the semiconductor control element 11, the first insulating element 13, and the second insulating element 15 are bonded to the first die pad 31 each by a bonding layer 69, the first drive element 12 is bonded to the second die pad 32 by a bonding layer 69, and the second drive element 14 is bonded to the third die pad 33 by a bonding layer 69. In FIG. 14, the bonding layers 69 are shaded with dots for the purpose of illustration. In the bonding process, a paste of a bonding material, which will be later hardened to form the bonding layers 69, is applied to the regions of the first die pad 31 where the semiconductor control element 11, the first insulating element 13 and the second insulating element 15 will be placed, the region of the second die pad 32 where the first drive element 12 will be placed and the region of the third die pad 33 where the second drive element 14 will be placed. Then, the semiconductor control element 11, the first drive element 12, the first insulating element 13, the second drive element 14 and the second insulating element 15 are placed on the layers of the applied bonding material. Next, reflowing is performed to melt and then harden the bonding material. Each of the second die pad 32 and the third die pad 33 is supported by a single lead like a cantilever. Despite this structure, the leadframe 80, being a flat frame, is less likely to be deformed by the mounting of the first drive element 12 and the second drive element 14.

Next, as shown in FIG. 14, the wires 61 to 67 are formed by wire bonding. The process of forming the wires involves heating the leadframe 80 while the leadframe 80 is held by a mold.

The process of forming the wire 61 begins with lowering a capillary toward the semiconductor control element 11 and presses the tip of a wire against a target electrode. In this state, by the action of the weight of the capillary, ultrasonic vibrations generated by the capillary, and so on, the wire tip is pressed against the electrode to form a bond. This completes first bonding. Then, the capillary is raised while the wire is continually fed. As a result, a ball bond is formed on the electrode. Next, the capillary is moved to a position directly above a target pad portion 54 (the middle protrusion 313 of the first die pad 31 in the case of forming the wire 61c) and then lowered to press the tip of the capillary against the pad portion 54. This causes the wire to be sandwiched between the capillary tip and the pad portion 54 to form a bond. This completes second bonding. Then, the capillary is raised to break the wire.

The process of forming a wire 62 includes first bonding of a wire to an electrode of the first drive element 12, forming a ball bond on the electrode, and second bonding of the wire on a target pad portion 55 (the second die pad 32 in the case of forming the wire 62a). The process of forming a wire 63 includes first bonding of a wire to an electrode of the second drive element 14, forming a ball bond on the electrode, and second bonding of the wire on a target pad portion 56 (the third die pad 33 in the case of forming the wire 63a).

The process of forming a wire 64 includes first bonding of a wire to an electrode of the first insulating element 13, forming a ball bond on the electrode, and second bonding of the wire on an electrode of the semiconductor control element 11. The process of forming a wire 65 includes first bonding of a wire to an electrode of the first insulating element 13, forming a ball bond on the electrode, and second bonding of the wire on an electrode of the first drive element 12. The process of forming a wire 66 includes first bonding of a wire to an electrode of the second insulating element 15, forming a ball bond on the electrode, and second bonding of the wire on an electrode of the semiconductor control element 11. The process of forming a wire 67 includes first bonding of a wire to an electrode of the second insulating element 15, forming a ball bond on the electrode, and second bonding of the wire on an electrode of the second drive element 14.

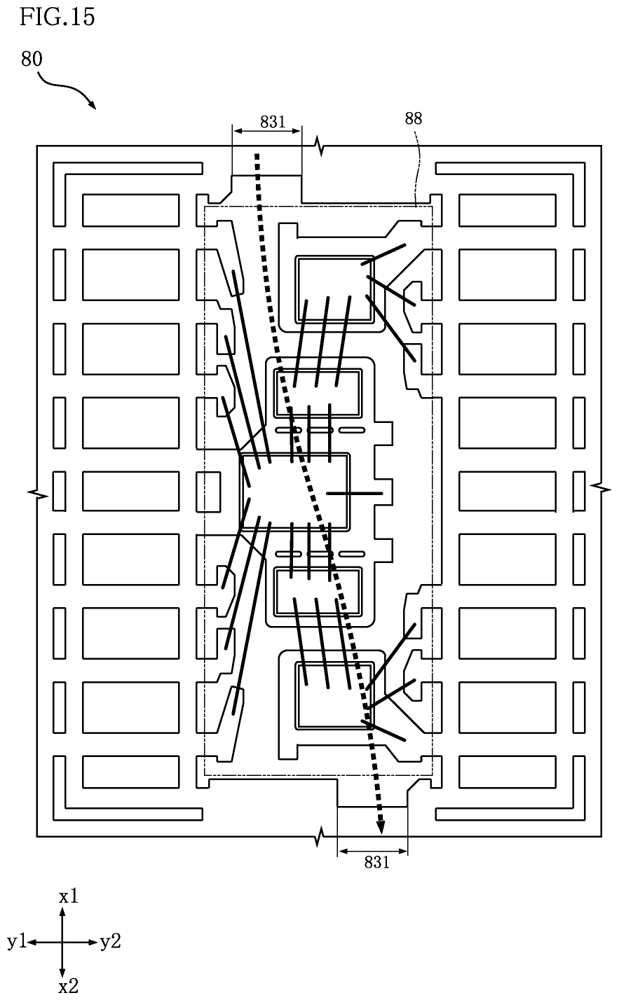

Next, a sealing resin 7 is formed. The sealing resin 7 is formed by transfer molding. This process includes placing the leadframe 80 into a mold defining a plurality of cavities 88. The leadframe 80 is placed as shown in FIG. 15, such that each portion of the electroconductive support member 2 to be covered later by the sealing resin 7 of a produced semiconductor device A10 is located within one of the cavities 88. Then, melted resin is introduced into the cavities 88. The melted resin flows into each cavity 88 through the inlet gate, which may be the cutout portion 831 on the x1 side in the x direction, flows along the dashed arrow shown in FIG. 15, and out from the cavity 88 through the outlet gate, which may be the cutout portion 831 on the x2 side in the x direction.

The melted resin injected into each cavity 88 is solidified to form the sealing resin 7, and resin burrs remaining outside the cavity 88 are removed by, for example, applying high-pressure water jet. Removing resin burrs from the site of the inlet gate leaves the first gate mark 75a on the sealing resin 7. Similarly, removing resin burrs from the site of the outlet gate leaves the second gate mark 76a on the sealing resin 7. This complete the formation of the sealing resin 7. Note that the gates used as the inlet and the outlet may be opposite.

Next, dicing is performed to isolate individual pieces, by separating the input-side terminals 51, the first output-side terminals 52 and the second output-side terminals 53 from the frame 81, the first tie bars 821, the second tie bars 822 and the dam bars 83. Through the processes described above, the semiconductor device A10 is manufactured.

The following describes advantages of the semiconductor device A10.

According to this embodiment, the semiconductor device A10 includes the first drive element 12 that generates a drive signal for a high-side switching element and the second drive element 14 that generates a drive signal for a low-side switching element. In other words, two switching elements of a half-bridge circuit can be driven by one semiconductor device A10. That is, the semiconductor device A10 includes one common semiconductor control element 11 for driving two switching elements and is more compact than two conventional semiconductor devices each of which includes a semiconductor control element for driving one switching element. The semiconductor device A10 can therefore reduce the footprint on the wiring board of an inverter device than the footprint of two conventional semiconductor devices. In addition, the semiconductor device A10 does not require spacing that needs to be provided between two conventional semiconductor devices mounted on a wiring board. The footprint of the semiconductor device A10 can be further reduced by the area of the spacing.

According to this embodiment, in addition, the semiconductor control element 11 is offset in the semiconductor device A10 to the y1 side in the y direction. Due to this arrangement, the wires 61 connecting the semiconductor control element 11 to the pad portions 54 extend at relatively small angles with the x direction. For example, the wires 61a and 61b form an angle of 20° or less with the x direction. In addition, the first insulating element 13 is located between the semiconductor control element 11 and the first drive element 12 in the x direction, and the second insulating element 15 is located between the semiconductor control element 11 and the second drive element 14 in the x direction. Due to this arrangement, the wires 64 to 67 extend at relatively small angles with the x direction. In the process of forming the sealing resin 7 (see FIG. 15), melted resin injected into each cavity 88 flows in the x direction. The wires 61 and 64 to 67 extending in the direction in which the melted resin flows are less likely to be displaced by the flow of melted resin. The wires 61 and 64 to 67 are therefore prevented from contacting or being too close to another wire or an element. In addition, the first drive element 12 and the second drive element 14 are offset in the semiconductor device A10 to the y2 side in the y direction. The center 13a of the first insulating element 13 is located between the center 11a of the semiconductor control element 11 and the center 12a of the first drive element 12 in the y direction. The center 15a of the second insulating element 15 is located between the center 11a of the semiconductor control element 11 and the center 14a of the second drive element 14 in the y direction. This arrangement can ensure the angles formed by the wires 64 to 67 with the x direction are not unduly large. In addition, the wires 64 and 65 can be shorter than with the arrangement where the center 13a of the first insulating element 13 is not located between the center 11a of the semiconductor control element 11 and the center 12a of the first drive element 12. Similarly, the wires 66 and 67 can be shorter than with the arrangement in which the center 15a of the second insulating element 15 is not located between the center 11a of the semiconductor control element 11 and the center 14a of the second drive element 14.

According to this embodiment, in addition, the semiconductor device A10 includes the first insulating element 13 that transmits a signal between the first drive element 12 and the semiconductor control element 11, while providing electrical insulation between the first drive element 12 and the semiconductor control element 11. This configuration can improve the voltage insulation between the input-side circuit, which includes the semiconductor control element 11, and the first output-side circuit, which includes the first drive element 12, in light of a significant potential difference possibly caused between the first drive element 12 and the semiconductor control element 11. According to this embodiment, in addition, the semiconductor device A10 includes the second insulating element 15 that transmits a signal between the second drive element 14 and the semiconductor control element 11, while providing electrical insulation between the second drive element 14 and the semiconductor control element 11. This configuration can improve the voltage insulation between the input-side circuit, which includes the semiconductor control element 11, and the second output-side circuit, which includes the second drive element 14, in light of a significant potential difference possibly caused between the second drive element 14 and the semiconductor control element 11. Thus, the semiconductor device A10 is operable with the high side and the low side being interchangeable.

According to this embodiment, in addition, the electroconductive support member 2 includes the first die pad 31, the second die pad 32, the third die pad 33, the input-side terminals 51, the first output-side terminals 52, the second output-side terminals 53 and the pad portions 54 to 56. The input-side terminals 51 are exposed on the side surface 73 of the sealing resin 7, and the first output-side terminals 52 and the second output-side terminals 53 are exposed on the side surface 74 of the sealing resin 7. In contrast, no portion of the electroconductive support member 2 is exposed on the side surfaces 75 and 76 of the sealing resin 7. For example, the protrusion 323 of the second die pad 32 is not exposed on the side surface 75 of the sealing resin 7. That is, the electroconductive support member 2 can increase the insulation distance between the portions exposed from the sealing resin 7 and electrically connected to the semiconductor control element 11 (the exposed portions of the input-side terminals 51) and the portions exposed from the sealing resin 7 and electrically connected to the second die pad 32 (the creepage distance along the surface of the sealing resin 7), as compared with when the protrusion 323 is provided as a support lead and exposed on the side surface 75 of the sealing resin 7. Also, the protrusion 333 of the third die pad 33 is not exposed on the side surface 76 of the sealing resin 7. The electroconductive support member 2 can increase the insulation distance between the input-side terminals 51 and the portion of the third die pad 33 exposed from the sealing resin 7 as compared with when the protrusion 333 is provided as a support lead and exposed on the side surface 76 of the sealing resin 7. The semiconductor device A10 can therefore improve the voltage insulation as compared with a configuration in which a portion of the electroconductive support member 2, such as a support lead, is exposed on the side surface 75 or 76. In addition, without a support lead exposed on the side surface 75, design flexibility is allowed in setting the location of the inlet gate (the cutout portion 831 on the x1 side) through which melted resin enters in the process of forming the sealing resin 7 (see FIG. 15). Similarly, without a support lead exposed on the side surface 76, design flexibility is allowed in setting the location of the outlet gate (the cutout portion 831 on the x2 side) through which melted resin exits in the process of forming the sealing resin 7.

According to this embodiment, in addition, the sealing resin 7 has a greater surface roughness on the top surface 71, the bottom surface 72 and the upper region 731 and the lower region 732 of the side surface 73 than on the middle region 733 of the side surface 73. Similarly, the sealing resin 7 has a greater surface roughness on the top surface 71, the bottom surface 72 and the upper region 741 and the lower region 742 of the side surface 74 than on the middle region 743 of the side surface 74. This can increase the creepage distance from the input-side terminal 51a to the first output-side terminal 52a along the upper region 731 of the side surface 73, the top surface 71 and the upper region 741 of the side surface 74, as well as the creepage distance from the input-side terminal 51a to the first output-side terminal 52a along the surfaces of the lower region 732 of the side surface 73, the bottom surface 72 and the lower region 742 of the side surface 74. Consequently, the semiconductor device A10 can further improve the voltage insulation.

According to this embodiment, in addition, the first inter-terminal distance L1 (the distance between the portion of the first output-side terminal 52b exposed from the sealing resin 7 and the portion of the second output-side terminal 53b exposed from the sealing resin 7) is at least three times greater than the second inter-terminal distance L2 (the distance between the portions of two adjacent first output-side terminals 52 exposed from the sealing resin 7). That is, a sufficient separation distance is provided between the exposed portions of the first output-side terminals 52 and the exposed portions of the second output-side terminals 53 in the x direction. Although a significant potential difference may occur between the first output-side terminals 52 and the second output-side terminals 53, the semiconductor device A10 provided with the sufficient separation distance can ensure high voltage insulation. In addition, the electroconductive support member 2 does not have any portion exposed in the region of the side surface 74 of the sealing resin 7 between the first output-side terminal 52b and the second output-side terminal 53b, and thus no metal part is present in that region. This means that a relatively long insulation distance is provided between the first output-side terminals 52 and the second output-side terminals 53. The semiconductor device A10 can therefore ensure high voltage insulation as compared with a configuration in which a portion of the electroconductive support member 2, such as a support lead, is exposed on the side surface 74.

According to this embodiment, in addition, the side surface 75 of the sealing resin 7 includes the first gate mark 75a having a rougher surface than the other region of the side surface 75. The first gate mark 75a is formed as a result of the process of forming the sealing resin 7 (see FIG. 15) during the manufacture of the semiconductor device A10, at the site of the inlet gate (the cutout portion 831 on the x1 side) through which melted resin enters. As shown in FIG. 1, the first gate mark 75a is offset to the y1 side in the y direction. Similarly, the side surface 76 of the sealing resin 7 includes the second gate mark 76a having a rougher surface than the other region of the side surface 76. The second gate mark 76a is formed as a result of the process of forming the sealing resin 7 during the manufacture of the semiconductor device A10, at the site of the outlet gate (the cutout portion 831 on the x2 side) through which melted resin exits. As shown in FIG. 1, the second gate mark 76a is offset to the y2 side in the y direction. This means that the melted resin injected in the process of forming the sealing resin 7 flows along a diagonal line across the cavity 88. This is effective for preventing formation of voids in the sealing resin 7.

According to this embodiment, the wire 61a does not overlap with the first insulating element 13 as viewed in the z direction. That is, the wire 61a is prevented from contacting or being too close to the first insulating element 13. Similarly, the wire 61b does not overlap with the second insulating element 15 as viewed in the z direction. That is, the wire 61c is prevented from contacting or being too close to the second insulating element 15. The wires 61a and 61b are connected to the semiconductor control element 11 and are components of the input-side circuit, which is held at a relatively low potential. The first insulating elements 13 and the second insulating element 15 include portions of the first and second output-side circuits, which are held at a relatively high potential. Preventing the wire 61a from being too close to the first insulating element 13 and the wire 61b from being too close to the second insulating element 15 serves to improve the voltage insulation of the semiconductor device A10. According to this embodiment, in addition, although the wire 61a may be pushed by the melted resin that flows through the inlet gate (the cutout portion 831 on the x1 side) in the process of forming the sealing resin 7 (see FIG. 15), the wire 61a is pushed in a direction away from the first insulating element 13. That is, the wire 61a is prevented from being too close to the first insulating element 13.

Although this embodiment describes the first gate mark 75a as being offset to the y1 side in the y direction and the second gate mark 76a to the y2 side, the present disclosure is not limited to this. The locations of the first gate mark 75a and the second gate mark 76a are not specifically limited. In other words, in the manufacture of the semiconductor device A10, the locations of the inlet gate and the outlet gate used in the process of forming the sealing resin 7 are not specifically limited. For example, the first gate mark 75a may be located offset to the y2 side in the y direction and the second gate mark 76a to the y1 side. This arrangement can still ensure that the melted resin injected in the process of forming the sealing resin 7 flows along a diagonal line across the cavity 88. This is effective for preventing formation of voids in the sealing resin 7. In another example, the first gate mark 75a and the second gate mark 76a may be both located offset to the y1 side in the y direction, both located offset to the y2 side in the y direction or both located offset to the center in the y direction. Since the semiconductor device A10 of this embodiment has no support lead exposed on the side surfaces 75 and 76, the locations of the inlet gate and the outlet gate can be flexibly determined.

Although this embodiment describes the electroconductive support member 2 not exposed on the side surfaces 75 and 76, the present disclosure is not limited to this. The electroconductive support member 2 may include a support lead exposed on the side surface 75 or 76.

In addition, although this embodiment describes the sealing resin 7 having a greater surface roughness on the top surface 71, the bottom surface 72, the upper region 731 and the lower region 732 of the side surface 73 and the upper region 741 and the lower region 742 of the side surface 74 than on the middle region 733 of the side surface 73 and the middle region 743 of the side surface 74, the present disclosure is not limited to this. For example, the sealing resin 7 may have about the same level of surface roughness on each of the surfaces 71 to 76. In such a case, the surface roughness of each of the surfaces 71 to 76 of the sealing resin 7 may be relatively small or relatively great (e.g., between 5 and 20 μm Rz).

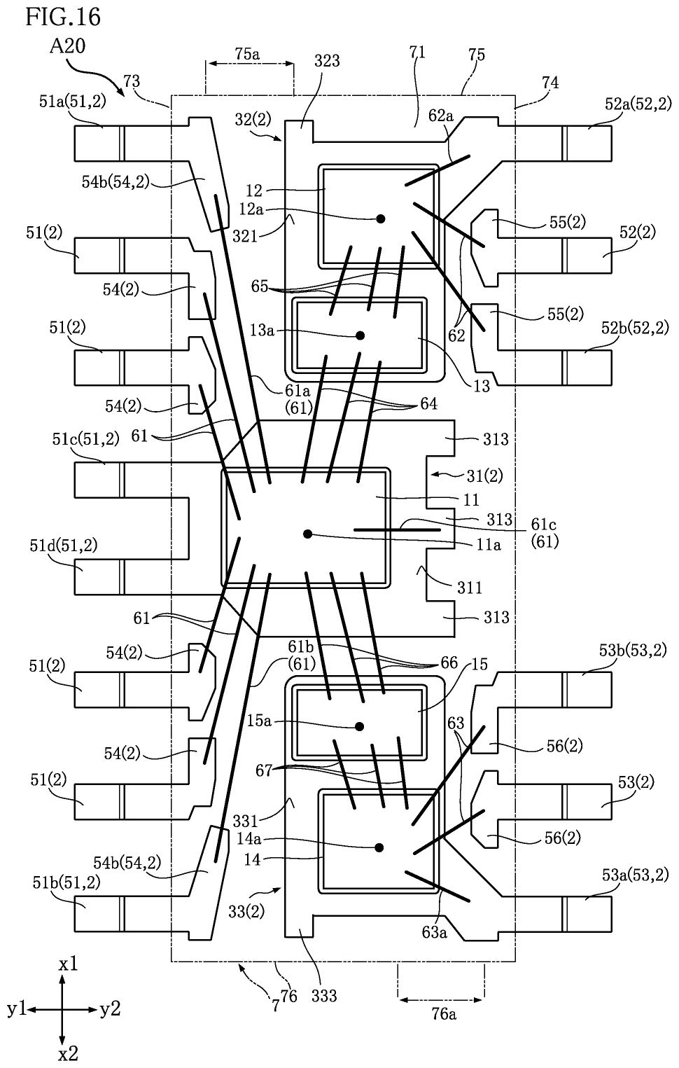

FIGS. 16 to 20 show other embodiments of the present disclosure. In these figures, the elements identical or similar to those of the embodiment described above are denoted by the same reference signs.

FIG. 16 is a view illustrating a semiconductor device A20 according to a second embodiment of the present disclosure. FIG. 16 is a plan view of the semiconductor device A20 and corresponds to FIG. 2. For convenience, FIG. 16 shows the sealing resin 7 as transparent and shows the outline of the sealing resin 7 in phantom (two-dot-dash lines). The semiconductor device A20 of this embodiment is different from the first embodiment in that the first insulating element 13 is mounted on the second die pad 32 and the second insulating element 15 is mounted on the third die pad 33.

The first die pad 31 of this embodiment has a smaller x-direction dimension than in the first embodiment. The second die pad 32 and the third die pad 33 have greater x-direction dimensions than in the first embodiment. In this embodiment, the first insulating element 13 is mounted on the second die pad 32, whereas the second insulating element 15 is mounted on the third die pad 33.

Also in this embodiment, the semiconductor device A20 includes the semiconductor control element 11, the first drive element 12 and the second drive element 14 and thus is capable of driving two switching elements of a half-bridge circuit. The semiconductor device A20 can be more compact than two conventional semiconductor devices together and can therefore reduce the footprint on the wiring board of an inverter device. In addition, the footprint of the semiconductor device A20 can be further reduced as the spacing required between two conventional semiconductor devices is not necessary. In addition, the semiconductor device A20 includes the same configuration as that of the semiconductor device A10 and can therefore achieve the same advantages as the semiconductor device A10.

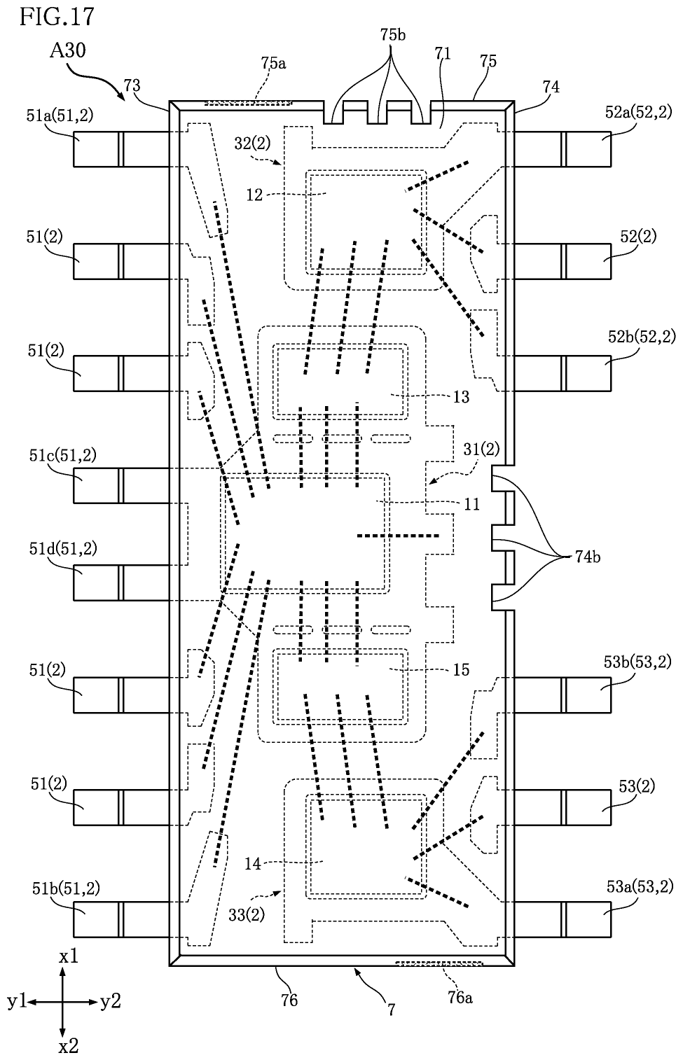

FIG. 17 is a view illustrating a semiconductor device A30 according to a third embodiment of the present disclosure. FIG. 17 is a plan view of the semiconductor device A30 and corresponds to FIG. 1. The semiconductor device A30 of this embodiment differs from the first embodiment in that the sealing resin 7 is formed with grooves.

In this embodiment, the sealing resin 7 additionally includes a first groove 74b and a second groove 75b. The first groove 74b is recessed from the side surface 74 in the y direction and extends in z direction from the top surface 71 to the bottom surface 72. The sealing resin 7 of this embodiment includes, but not limited to, three first grooves 74b at equal intervals in the x direction. The first grooves 74b are rectangular as viewed in the z direction. The shape of each first groove 74b as viewed in the z direction is not limited to this and may be semi-circular, for example. The first grooves 74b are located in a region of the side surface 74 between the first output-side terminal 52b and the second output-side terminal 53b. The second groove 75b is recessed from the side surface 75 in the x direction and extends in z direction from the top surface 71 to the bottom surface 72. The sealing resin 7 of this embodiment includes three second grooves 75b at equal intervals in the y direction. The number and the location of the second grooves 75b to be provided are not limited. The second grooves 75b are rectangular as viewed in the z direction. The shape of each second groove 75b as viewed in the z direction is not limited to this and may be semi-circular, for example. The second grooves 75b are formed in a region of the side surface 75 other than the first gate mark 75a. The sealing resin 7 may additionally include one or more third grooves recessed from the side surface 76 in the x direction and extending in the z direction from the top surface 71 to the bottom surface 72.

Also in this embodiment, the semiconductor device A30 includes the semiconductor control element 11, the first drive element 12 and the second drive element 14 and thus is capable of driving two switching elements of a half-bridge circuit. The semiconductor device A30 can be more compact than two conventional semiconductor devices together and can therefore reduce the footprint on the wiring board of an inverter device. In addition, the footprint of the semiconductor device A30 can be further reduced as the spacing required between two conventional semiconductor devices is not necessary. In addition, the semiconductor device A30 includes the same configuration as that of the semiconductor device A10 and can therefore achieve the same advantages as the semiconductor device A10.

According to this embodiment, in addition, the sealing resin 7 has the first grooves 74b in a region of the side surface 74 between the first output-side terminal 52b and the second output-side terminal 53b. The creepage distance from the first output-side terminal 52b to the second output-side terminal 53b along the side surface 74 is greater with the first grooves 74b than without. Consequently, the semiconductor device A30 can further improve the voltage insulation. In addition, the sealing resin 7 has the second grooves 75b on the side surface 75. The creepage distance from the input-side terminal 51a to the first output-side terminal 52a along the side surfaces 73, 75 and 74 of the sealing resin 7 is greater with the second grooves 75b than without. Consequently, the semiconductor device A30 can further improve the voltage insulation.

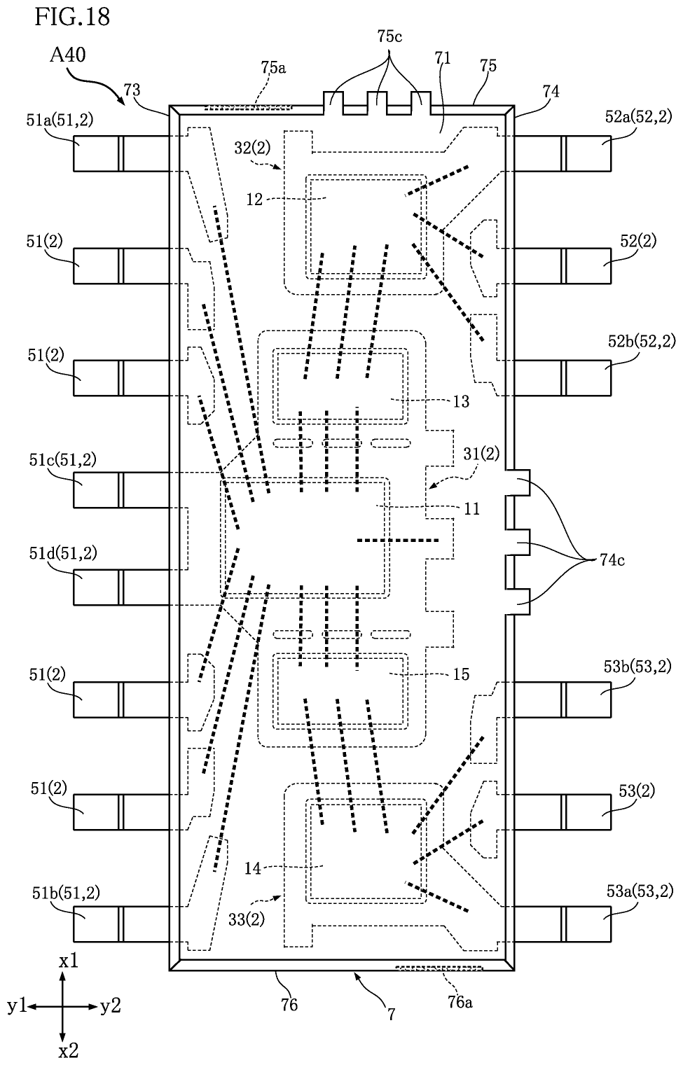

FIG. 18 is a view illustrating a semiconductor device A40 according to a fourth embodiment of the present disclosure. FIG. 18 is a plan view of the semiconductor device A40 and corresponds to FIG. 1. The semiconductor device A40 of this embodiment differs from the first embodiment in that the sealing resin 7 is formed with protrusions.

The sealing resin 7 of this embodiment includes a first protrusion 74c and a second protrusion 75c. The first protrusion 74c protrudes from the side surface 74 in the y direction and extends in z direction from the top surface 71 to the bottom surface 72. The sealing resin 7 of this embodiment includes, but not limited to, three first protrusions 74c at equal intervals in the x direction. The first protrusions 74c are rectangular as viewed in the z direction. The shape of each first protrusion 74c as viewed in the z direction is not limited to this and may be semi-circular, for example. The first protrusions 74c are located in a region of the side surface 74 between the first output-side terminal 52b and the second output-side terminal 53b. The second protrusion 75c protrudes from the side surface 75 in the x direction and extends in z direction from the top surface 71 to the bottom surface 72. The sealing resin 7 of this embodiment includes three second protrusions 75c at equal intervals in the y direction. The number and the location of the second protrusions 75c to be provided are not limited. The second protrusions 75c are rectangular as viewed in the z direction. The shape of each second protrusion 75c as viewed in the z direction is not limited to this and may be semi-circular, for example. The second protrusions 75c are formed in a region of the side surface 75 other than the first gate mark 75a. The sealing resin 7 may additionally include one or more third protrusions protruding from the side surface 76 in the x direction and extending in the z direction from the top surface 71 to the bottom surface 72.

Also in this embodiment, the semiconductor device A40 includes the semiconductor control element 11, the first drive element 12 and the second drive element 14 and thus is capable of driving two switching elements of a half-bridge circuit. The semiconductor device A40 can be more compact than two conventional semiconductor devices together and can therefore reduce the footprint on the wiring board of an inverter device. In addition, the footprint of the semiconductor device A40 can be further reduced as the spacing required between two conventional semiconductor devices is not necessary. In addition, the semiconductor device A40 includes the same configuration as that of the semiconductor device A10 and can therefore achieve the same advantages as the semiconductor device A10.

According to this embodiment, in addition, the sealing resin 7 has the first protrusions 74c in a region of the side surface 74 between the first output-side terminal 52b and the second output-side terminal 53b. The creepage distance from the first output-side terminal 52b to the second output-side terminal 53b along the side surface 74 is greater with the first protrusions 74c than without. Consequently, the semiconductor device A40 can further improve the voltage insulation. In addition, the sealing resin 7 has the second protrusions 75c on the side surface 75. The creepage distance from the input-side terminal 51a to the first output-side terminal 52a along the side surfaces 73, 75 and 74 of the sealing resin 7 is greater with the second protrusions 75c than without. Consequently, the semiconductor device A40 can further improve the voltage insulation.

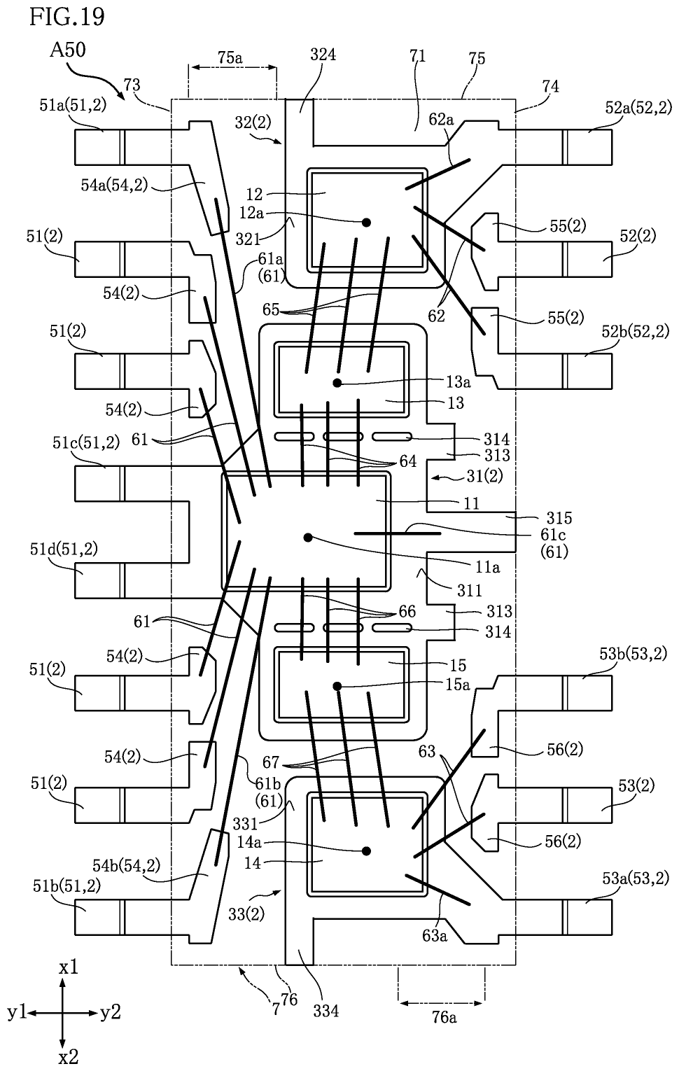

FIG. 19 is a view illustrating a semiconductor device A50 according to a fifth embodiment of the present disclosure. FIG. 19 is a plan view of the semiconductor device A50 and corresponds to FIG. 2. For convenience, FIG. 19 shows the sealing resin 7 as transparent and shows the outline of the sealing resin 7 in phantom (two-dot-dash lines). The semiconductor device A50 of this embodiment differs from the first embodiment in that the first die pad 31, the second die pad 32 and the third die pad 33 are each additionally supported by a support lead.

The first die pad 31 of this embodiment includes a support lead 315 instead of the middle one of the three protrusions 313. The support lead 315 protrudes outward from the side surface of the first die pad 31 on the y2 side in the y direction and supports the first die pad 31. The end surface of the support lead 315 on the y2 side in the y direction is exposed on the side surface 74 of the sealing resin 7. The support lead 315 is a portion that is tied to the first die pad 31 and a first tie bar 821 in the leadframe 80 and cut off from the first tie bar 821 in the dicing process. The cut surface formed by this cutting is the end surface on the y2 side in the y direction and exposed on the side surface 74 of the sealing resin 7.

In addition, the second die pad 32 of this embodiment includes a support lead 324 instead of the protrusion 323. The support lead 324 protrudes outward from the side surface of the second die pad 32 on the x1 side in the x direction and supports the second die pad 32. The end surface of the support lead 324 on the x1 side in the x direction is exposed on the side surface 75 of the sealing resin 7. The support lead 324 is a portion that is tied to the second die pad 32 and a dam bar 83 in the leadframe 80 and cut off from the dam bar 83 in the dicing process. The cut surface formed by this cutting is the end surface on the x1 side in the x direction and exposed on the side surface 75 of the sealing resin 7.

In addition, the third die pad 33 of this embodiment includes a support lead 334 instead of the protrusion 333. The support lead 334 protrudes outward from the side surface of the third die pad 33 on the x2 side in the x direction and supports the third die pad 33. The end surface of the support lead 334 on the x2 side in the x direction is exposed on the side surface 76 of the sealing resin 7. The support lead 334 is a portion that is tied to the third die pad 33 and a dam bar 83 in the leadframe 80 and cut off from the dam bar 83 in the dicing process. The cut surface formed by this cutting is the end surface on the x2 side in the x direction and exposed on the side surface 76 of the sealing resin 7.

Also in this embodiment, the semiconductor device A50 includes the semiconductor control element 11, the first drive element 12 and the second drive element 14 and thus is capable of driving two switching elements of a half-bridge circuit. The semiconductor device A50 can be more compact than two conventional semiconductor devices together and can therefore reduce the footprint on the wiring board of an inverter device. In addition, the footprint of the semiconductor device A50 can be further reduced as the spacing required between two conventional semiconductor devices is not necessary. In addition, the semiconductor device A50 includes the same configuration as that of the semiconductor device A10 and can therefore achieve the same advantages as the semiconductor device A10.

According to this embodiment, the support lead 315 provides additional support to the first die pad 31. The first die pad 31 can therefore be held more stable during the process of bonding the semiconductor control element 11, the first insulating element 13 and the second insulating element 15 to the first die pad 31 and also during the process of forming the wires 61. In addition, the support lead 324 provides additional support to the second die pad 32. The second die pad 32 can therefore be held more stable during the process of bonding the first drive element 12 to the second die pad 32 and also during the process of forming the wires 62. In addition, the support lead 334 provides additional support to the third die pad 33. The third die pad 33 can therefore be held more stable during the process of bonding the second drive element 14 to the third die pad 33 and also during the process of forming the wires 63.

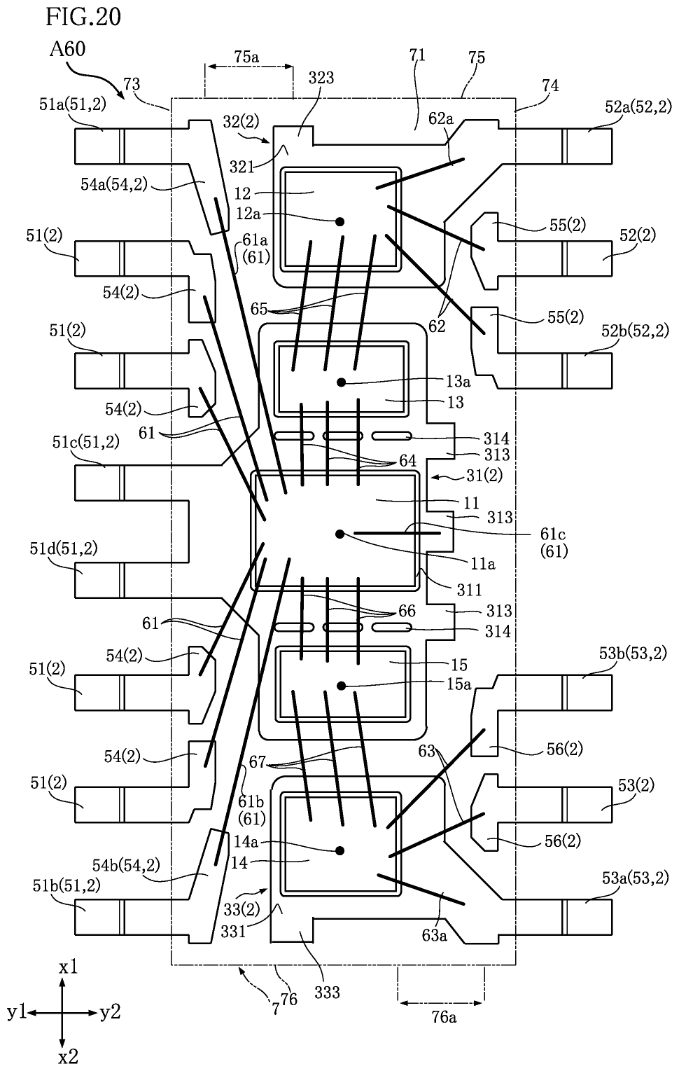

FIG. 20 is a view illustrating a semiconductor device A60 according to a sixth embodiment of the present disclosure. FIG. 20 is a plan view of the semiconductor device A60 and corresponds to FIG. 2. For convenience, FIG. 20 shows the sealing resin 7 as transparent and shows the outline of the sealing resin 7 in phantom (two-dot-dash lines). The semiconductor device A60 of this embodiment differs from the first embodiment in that the semiconductor control element 11, the first drive element 12, the first insulating element 13, the second drive element 14 and the second insulating element 15 are aligned in the x direction.

According to this embodiment, the center 11a of the semiconductor control element 11, the center 12a of the first drive element 12, the center 13a of the first insulating element 13, the center 14a of the second drive element 14, and the center 15a of the second insulating element 15 are aligned in the x direction.

Also in this embodiment, the semiconductor device A60 includes the semiconductor control element 11, the first drive element 12 and the second drive element 14 and thus is capable of driving two switching elements of a half-bridge circuit. The semiconductor device A60 can be more compact than two conventional semiconductor devices together and can therefore reduce the footprint on the wiring board of an inverter device. In addition, the footprint of the semiconductor device A60 can be further reduced as the spacing required between two conventional semiconductor devices is not necessary. In addition, the semiconductor device A60 includes the same configuration as that of the semiconductor device A10 and can therefore achieve the same advantages as the semiconductor device A10.

The semiconductor device according to the present disclosure is not limited to the foregoing embodiments. Various design changes can be made to the specific configuration of each part of the semiconductor device according to present disclosure. The present disclosure covers the embodiments described in the following clauses.

Clause 1.

A semiconductor device comprising:
a semiconductor control element;
a first drive element spaced apart from the semiconductor control element to a first side in a first direction perpendicular to a thickness direction of the semiconductor control element, the first drive element receiving a signal transmitted from the semiconductor control element;
a second drive element spaced apart from the semiconductor control element to a second side opposite the first side in the first direction, the second drive element receiving a signal transmitted from the semiconductor control element;
a first insulating element located between the semiconductor control element and the first drive element in the first direction, the first insulating element relaying a signal transmitted from the semiconductor control element to the first drive element and providing electrical insulation between the semiconductor control element and the first drive element;
a second insulating element located between the semiconductor control element and the second drive element in the first direction, the second insulating element relaying a signal transmitted from the semiconductor control element to the second drive element and providing electrical insulation between the semiconductor control element and the second drive element; and
a sealing resin covering the semiconductor control element.

Clause 2.

The semiconductor device according to Clause 1, further comprising an electroconductive support member including a first die pad on which the semiconductor control element is mounted, a second die pad on which the first drive element is mounted and a third die pad on which the second drive element is mounted.

Clause 3.

The semiconductor device according to Clause 2, wherein the first insulating element and the second insulating element are mounted on the first die pad.

Clause 4.

The semiconductor device according to Clause 2, wherein the first insulating element is mounted on the second die pad, and
the second insulating element is mounted on the third die pad.

Clause 5.

The semiconductor device according to any one of Clauses 2 to 4, wherein the electroconductive support member includes a plurality of input-side terminals arranged side by side in the first direction, and at least one of the plurality of input-side terminals is electrically connected to the semiconductor control element.

Clause 6.

The semiconductor device according to Clause 5, further comprising a first wire and a second wire,
wherein the plurality of input-side terminals include an input-side first terminal that is located farthest on the first side and an input-side second terminal that is located farthest on the second side,
the first wire electrically connects the semiconductor control element and the input-side first terminal and does not overlap with the first insulating element as viewed in the thickness direction, and
the second wire electrically connects the semiconductor control element and the input-side second terminal and does not overlap with the second insulating element as viewed in the thickness direction.

Clause 7.

The semiconductor device according to Clause 6, wherein each of the first wire and the second wire forms an angle of 20° or less with the first direction.

Clause 8.

The semiconductor device according to any one of Clauses 5 to 7, wherein the plurality of input-side terminals includes an input-side support terminal connected to the first die pad.

Clause 9.

The semiconductor device according to any one of Clauses 2 to 8, wherein the electroconductive support member includes:
a plurality of first output-side terminals arranged side by side in the first direction, at least one of the plurality of first output-side terminals being electrically connected to the first drive element; and
a plurality of second output-side terminals arranged side by side in the first direction on the second side with respect to the plurality of first output-side terminal, at least one of the plurality of second output-side terminals being electrically connected to the second drive element.

Clause 10.

The semiconductor device according to Clause 9, wherein the plurality of first output-side terminals include a single first output-side support terminal connected to the second die pad, and
the plurality of second output-side terminals include a single second output-side support terminal connected to the third die pad.

Clause 11.

The semiconductor device according to Clause 9 or 10, wherein each of the plurality of first output-side terminals includes a first exposed portion that is exposed from the sealing resin, and each of the plurality of second output-side terminals includes a second exposed portion that is exposed from the sealing resin, and
the plurality of first output-side terminals include a first output-side innermost terminal that is located farthest on the second side, and the plurality of second output-side terminals include a second output-side innermost terminal that is located farthest on the first side,
the first exposed portion of the first output-side innermost terminal and the second exposed portion of the second output-side innermost terminal are spaced apart from each other by a first inter-terminal distance,
the plurality of first exposed portions are spaced apart from each other to define one or more separation distances between each pair of two adjacent first exposed portions of the plurality first exposed portions, and a greatest one of the separation distances is defined as a second inter-terminal distance, and
the first inter-terminal distance is at least three times greater than the second inter-terminal distance.

Clause 12.

The semiconductor device according to Clause 11, wherein the sealing resin includes a first side surface from which the plurality of first output-side terminals and the plurality of second output-side terminals protrude, and
the electroconductive support member is not exposed in a region of the first side surface between the first output-side innermost terminal and the second output-side innermost terminal.

Clause 13.

The semiconductor device according to Clause 12, wherein the sealing resin includes a first groove recessed from the first side surface and extending in the thickness direction, and
the first groove is located between the first output-side innermost terminal and the second output-side innermost terminal in the first direction.

Clause 14.

The semiconductor device according to Clause 12 or 13, wherein the sealing resin includes a top surface located on a side opposite the first die pad with respect to the semiconductor control element in the thickness direction and a bottom surface opposite the top surface in the thickness direction,
the first side surface includes a first region connected to the top surface, a second region connected to the bottom surface, and a third region connected to the first region and the second region and from which the plurality of first output-side terminals and the plurality of second output-side terminals protrude, and
the top surface, the bottom surface, the first region and the second region each have a greater surface roughness than the third region.

Clause 15.

The semiconductor device according to any one of Clauses 2 to 14, wherein in a second direction perpendicular to the thickness direction and the first direction, the first insulating element has a center between a center of the semiconductor control element and a center of the first drive element and the second insulating element has a center between the center of the semiconductor control element and a center of the second drive element, and
the center of the first drive element and the center of the second drive element are located on a same side in the second direction with respect to the center of the semiconductor control element.

Clause 16.

The semiconductor device according to Clause 15, wherein the sealing resin includes a second side surface located on the first side in the first direction, and
the electroconductive support member is not exposed on the second side surface.

Clause 17.

The semiconductor device according to Clause 16, wherein the sealing resin includes a second groove recessed from the second side surface in the first direction and extending in the thickness direction.

Clause 18.

The semiconductor device according to Clause 16 or 17, wherein the second side surface includes a first gate mark having a greater surface roughness than another region of the second side surface, and
the first gate mark is offset in the second direction to a side closer to the center of the semiconductor control element with respect to the center of the first drive element.

Clause 19.

The semiconductor device according to Clause 18, wherein the sealing resin includes a third side surface located on the second side in the first direction,
the third side surface includes a second gate mark having a greater surface roughness than another region of the third side surface, and
the second gate mark is offset in the second direction to a side opposite the center of the semiconductor control element with respect to the center of the second drive element.

### REFERENCE NUMERALS

A10, A20, A30, A40, A50, A60: semiconductor device
11: semiconductor control element
11a: center
12: first drive element
12a: center
13: first insulating element
13a: center
14: second drive element
14a: center
15: second insulating element
15a: center
2: electroconductive support member
31: first die pad
311: obverse surface
312: reverse surface
313: protrusion
314: groove
315: support lead
32: second die pad
321: obverse surface
322: reverse surface
323: protrusion
324: support lead
33: third die pad
331: obverse surface
332: reverse surface
333: protrusion
334: support lead
51, 51a, 51b, 51c, 51d: input-side terminal
52, 52a, 52b: first output-side terminal
53, 53a, 53b: second output-side terminal
54, 54a, 54b, 55, 56: pad portion
61, 61a, 61b, 61c, 62, 62a: wire
63, 63a, 64 to 67: wire
69: bonding layer
7: sealing resin
71: top surface
72: bottom surface
73: side surface
731: upper region
732: lower region
733: middle region
74: side surface
741: upper region
742: lower region
743: middle region
74b: first groove
74c: first protrusion
75: side surface
751: upper region
752: lower region
753: middle region
75a: first gate mark
75b: second groove
75c: second protrusion
76: side surface
761: upper region
762: lower region
763: middle region
76a: second gate mark
80: leadframe
80A: obverse surface
80B: reverse surface
81: frame
821: first tie bar
822: second tie bar
83: dam bar
831: cutout portion
88: cavity

1. A semiconductor device comprising:
a semiconductor control element;
a first drive element located on a first side in a first direction perpendicular to a thickness direction of the semiconductor control element with respect to the semiconductor control element, the first drive element receiving a signal transmitted from the semiconductor control element;
a second drive element located on a second side opposite the first side in the first direction with respect to the semiconductor control element, the second drive element receiving a signal transmitted from the semiconductor control element;
a first insulating element located between the semiconductor control element and the first drive element in the first direction, the first insulating element relaying a signal transmitted from the semiconductor control element to the first drive element and providing electrical insulation between the semiconductor control element and the first drive element;
a second insulating element located between the semiconductor control element and the second drive element in the first direction, the second insulating element relaying a signal transmitted from the semiconductor control element to the second drive element and providing electrical insulation between the semiconductor control element and the second drive element; and
a sealing resin covering the semiconductor control element.

2. The semiconductor device according to claim 1, further comprising an electroconductive support member including a first die pad on which the semiconductor control element is mounted, a second die pad on which the first drive element is mounted and a third die pad on which the second drive element is mounted.

3. The semiconductor device according to claim 2, wherein the first insulating element and the second insulating element are mounted on the first die pad.

4. The semiconductor device according to claim 2, wherein the first insulating element is mounted on the second die pad, and
the second insulating element is mounted on the third die pad.

5. The semiconductor device according to claim 2, wherein the electroconductive support member includes a plurality of input-side terminals arranged side by side in the first direction, and at least one of the plurality of input-side terminals is electrically connected to the semiconductor control element.

6. The semiconductor device according to claim 5, further comprising a first wire and a second wire,
wherein the plurality of input-side terminals include an input-side first terminal that is located farthest on the first side and an input-side second terminal that is located farthest on the second side,
the first wire electrically connects the semiconductor control element and the input-side first terminal and does not overlap with the first insulating element as viewed in the thickness direction, and
the second wire electrically connects the semiconductor control element and the input-side second terminal and does not overlap with the second insulating element as viewed in the thickness direction.

7. The semiconductor device according to claim 6, wherein each of the first wire and the second wire forms an angle of 20° or less with the first direction.

8. The semiconductor device according to claim 5, wherein the plurality of input-side terminals includes an input-side support terminal connected to the first die pad.

9. The semiconductor device according to claim 2, wherein the electroconductive support member includes:
a plurality of first output-side terminals arranged side by side in the first direction, at least one of the plurality of first output-side terminals being electrically connected to the first drive element; and
a plurality of second output-side terminals arranged side by side in the first direction on the second side with respect to the plurality of first output-side terminal, at least one of the plurality of second output-side terminals being electrically connected to the second drive element.

10. The semiconductor device according to claim 9, wherein the plurality of first output-side terminals include a single first output-side support terminal connected to the second die pad, and
the plurality of second output-side terminals include a single second output-side support terminal connected to the third die pad.

11. The semiconductor device according to claim 9, wherein each of the plurality of first output-side terminals includes a first exposed portion that is exposed from the sealing resin, and each of the plurality of second output-side terminals includes a second exposed portion that is exposed from the sealing resin, and
the plurality of first output-side terminals include a first output-side innermost terminal that is located farthest on the second side, and the plurality of second output-side terminals include a second output-side innermost terminal that is located farthest on the first side,
the first exposed portion of the first output-side innermost terminal and the second exposed portion of the second output-side innermost terminal are spaced apart from each other by a first inter-terminal distance,
the plurality of first exposed portions are spaced apart from each other to define one or more separation distances between each pair of two adjacent first exposed portions of the plurality first exposed portions, and a greatest one of the separation distances is defined as a second inter-terminal distance, and
the first inter-terminal distance is at least three times greater than the second inter-terminal distance.

12. The semiconductor device according to claim 11, wherein the sealing resin includes a first side surface from which the plurality of first output-side terminals and the plurality of second output-side terminals protrude, and
the electroconductive support member is not exposed in a region of the first side surface between the first output-side innermost terminal and the second output-side innermost terminal.

13. The semiconductor device according to claim 12, wherein the sealing resin includes a first groove recessed from the first side surface and extending in the thickness direction, and
the first groove is located between the first output-side innermost terminal and the second output-side innermost terminal in the first direction.

14. The semiconductor device according to claim 12, wherein the sealing resin includes a top surface located on a side opposite the first die pad with respect to the semiconductor control element in the thickness direction and a bottom surface opposite the top surface in the thickness direction,
the first side surface includes a first region connected to the top surface, a second region connected to the bottom surface, and a third region connected to the first region and the second region and from which the plurality of first output-side terminals and the plurality of second output-side terminals protrude, and
the top surface, the bottom surface, the first region and the second region each have a greater surface roughness than the third region.

15. The semiconductor device according to claim 2, wherein in a second direction perpendicular to the thickness direction and the first direction, the first insulating element has a center between a center of the semiconductor control element and a center of the first drive element and the second insulating element has a center between the center of the semiconductor control element and a center of the second drive element, and
the center of the first drive element and the center of the second drive element are located on a same side in the second direction with respect to the center of the semiconductor control element.

16. The semiconductor device according to claim 15, wherein the sealing resin includes a second side surface located on the first side in the first direction, and
the electroconductive support member is not exposed on the second side surface.

17. The semiconductor device according to claim 16, wherein the sealing resin includes a second groove recessed from the second side surface in the first direction and extending in the thickness direction.

18. The semiconductor device according to claim 16, wherein the second side surface includes a first gate mark having a greater surface roughness than another region of the second side surface, and
the first gate mark is offset in the second direction to a side closer to the center of the semiconductor control element with respect to the center of the first drive element.

19. The semiconductor device according to claim 18, wherein the sealing resin includes a third side surface located on the second side in the first direction,
the third side surface includes a second gate mark having a greater surface roughness than another region of the third side surface, and
the second gate mark is offset in the second direction to a side opposite the center of the semiconductor control element with respect to the center of the second drive element.
